(19) United States
(12) Patent Application Publication
(10) Pub. No.: US 2014/0056056 A1
(43) Pub. Date: Feb. 27, 2014

(54) METHOD FOR READING DATA FROM NONVOLATILE MEMORY ELEMENT, AND NONVOLATILE MEMORY DEVICE

(71) Applicant: Panasonic Corporation, Osaka (JP)

(72) Inventors: Takeshi Takagi, Kyoto (JP); Zhiqiang Wei, Osaka (JP); Takeki Ninomiya, Osaka (JP)

(73) Assignee: Panasonic Corporation, Osaka (JP)

(21) Appl. No.: 14/111,831

(22) PCT Filed: Feb. 15, 2013
(86) PCT No.: PCT/JP2013/000835

§ 371 Date: Oct. 15, 2013

(30) Foreign Application Priority Data
Feb. 17, 2012 (JP) 2012-032318

(51) Int. Cl. G11C 13/00

(52) U.S. Cl. CPC G11C 13/004
USPC 365/148

(57) ABSTRACT

A method for reading data from a nonvolatile memory element including a first electrode, a second electrode, and a variable resistance layer which includes a local region having a higher degree of oxygen deficiency than a surrounding region, the method including: applying a third voltage pulse between the first electrode and the second electrode, the third voltage pulse having a voltage with an absolute value smaller than absolute values of voltages of the first voltage pulse and the second voltage pulse; and reading the resistance state of the variable resistance layer by applying a fourth voltage pulse between the first electrode and the second electrode after the applying of a third voltage pulse, the fourth voltage pulse having a voltage with an absolute value smaller than the absolute values of the voltages of the first voltage pulse and the second voltage pulse.

### TECHNICAL FIELD

The present invention relates to a method for reading data from a variable resistance nonvolatile memory element whose resistance value changes according to an applied electric signal, and to a nonvolatile memory device which executes the method.

### BACKGROUND ART

Recent years have seen the development of digital technology. As such, there is an increased demand for larger capacity, reduced writing power consumption, reduced time for writing and reading, and extended operational life in nonvolatile memory devices. In view of such a demand, research and development is advancing on a nonvolatile memory device including a variable resistance nonvolatile memory element which has a characteristic in which a resistance value reversibly changes according to electrical signals.

A nonvolatile memory element has a simple structure in which a variable resistance layer is held between a bottom electrode and a top electrode. An electric pulse having a voltage no smaller than a threshold value is applied to the variable resistance layer between the top electrode and the bottom electrode. With this, the variable resistance layer is changed to a high resistance state or a low resistance state. The resistance state and data are associated with each other, and the nonvolatile memory element thus records information.

As a result of recent researches, the physical mechanism of resistance change is believed to be as follows. A conductive filament, that is, a current path (conduction path) in which current density becomes locally high is formed in a binary transition metal oxide included in the variable resistance layer, and the change in resistance occurs with a change in defect density in the filament due to oxidation-reduction (e.g., see patent literature (PTL) 1, 2 and non patent literature (NPL) 1).

### CITATION LIST

### Patent Literature

[PTL 1]
U.S. Pat. No. 6,473,332
[PTL 2]
Japanese Unexamined Patent Application Publication No. 2008-306157

### Non Patent Literature

[NPL 1]
R. Waser et al., Advanced Materials, NO21, 2009, pp. 2632-2663

### SUMMARY OF INVENTION

### Technical Problem

In a variable resistance nonvolatile memory element, the resistance state, which is once set, sometimes changes in a long or a short finite time.

The inventors found, in addition to a deterioration of information caused by a gradual change in resistance value over a relatively long period of time (retention characteristic deterioration), a new type of phenomenon regarding a change in resistance value, that is, a resistance value increases or decreases in a short period of time (hereinafter called “fluctuation in resistance value” or simply called “fluctuation”).

However, an effective method for reducing a change (fluctuation) in a resistance value that occurs in a short period of time has not been presented, and an error is observed in reading a resistance state due to an effect of fluctuation.

In view of the above, the present invention is for providing a method for reading data from a nonvolatile memory element and a nonvolatile memory device which can reduce the error in reading due to the effect of fluctuation.

### Solution to Problem

In order to achieve the above object, a method for reading data from a variable resistance nonvolatile memory element according an aspect of the present invention is a method for reading data from a variable resistance nonvolatile memory element which (i) includes a first electrode, a second electrode, and a variable resistance layer which is positioned between the first electrode and the second electrode, comprises a metal oxide, and includes a local region having a degree of oxygen deficiency higher than a degree of oxygen deficiency of a surrounding region of the local region, (ii) has a characteristic that the variable resistance layer changes from a low resistance state to a high resistance state in response to application of a first voltage pulse between the first electrode and the second electrode, and the variable resistance layer changes from the high resistance state to the low resistance state in response to application of a second voltage pulse between the first electrode and the second electrode, and (iii) stores data corresponding to the resistance state of the variable resistance layer, the method including: applying a third voltage pulse between the first electrode and the second electrode of the variable resistance layer which has been changed to the high resistance state or the low resistance state, the third voltage pulse having a voltage with an absolute value smaller than absolute values of voltages of the first voltage pulse and the second voltage pulse; and reading the resistance state of the variable resistance layer by applying a fourth voltage pulse between the first electrode and the second electrode after the applying of a third voltage pulse, the fourth voltage pulse having a voltage with an absolute value smaller than the absolute values of the voltages of the first voltage pulse and the second voltage pulse.

Furthermore, a method for reading data from a variable resistance nonvolatile memory element according to an aspect of the present invention is a method for reading data from a variable resistance nonvolatile memory element which (i) includes a first electrode, a second electrode, and a variable resistance layer which is positioned between the first electrode and the second electrode, comprises a metal oxide, and includes a local region having a degree of oxygen deficiency higher than a degree of oxygen deficiency of a surrounding region of the local region, (ii) has a characteristic that the variable resistance layer changes from a low resistance state to a high resistance state in response to application of a first current pulse between the first electrode and the second electrode, and the variable resistance layer changes from the high resistance state to the low resistance state in response to application of a second current pulse between the first electrode and the second electrode, and (iii) stores data corresponding to the resistance state of the variable resistance layer, the method including: applying a third current pulse between the first electrode and the second electrode of the variable resistance layer which has been changed to the high resistance state or the low resistance state, the third current pulse having a current with an absolute value smaller than absolute values of currents of the first current pulse and the second current pulse; and reading the resistance state of the variable resistance layer by applying a fourth current pulse between the first electrode and the second electrode after the applying of a third current pulse, the fourth current pulse having a current with an absolute value smaller than the absolute values of the currents of the first current pulse and the second current pulse.

Furthermore, a nonvolatile memory device according to an aspect of the present invention is a nonvolatile memory device including a variable resistance nonvolatile memory element which (i) includes a first electrode, a second electrode, and a variable resistance layer which is positioned between the first electrode and the second electrode, comprises a metal oxide, and includes a local region having a degree of oxygen deficiency higher than a degree of oxygen deficiency of a surrounding region of the local region, (ii) has a characteristic that the variable resistance layer changes from a low resistance state to a high resistance state in response to application of a first voltage pulse between the first electrode and the second electrode, and the variable resistance layer changes from the high resistance state to the low resistance state in response to application of a second voltage pulse between the first electrode and the second electrode, and (iii) stores data corresponding to the resistance state of the variable resistance layer, the nonvolatile memory device including: a first voltage application unit configured to apply a third voltage pulse between the first electrode and the second electrode of the variable resistance layer which has been changed to the high resistance state or the low resistance state, the third voltage pulse having a voltage with an absolute value smaller than absolute values of voltages of the first voltage pulse and the second voltage pulse; a second voltage application unit configured to apply a fourth voltage pulse between the first electrode and the second electrode of the variable resistance layer which has been changed to the high resistance state or the low resistance state, the fourth voltage pulse being for reading and having a voltage with an absolute value smaller than the absolute values of the voltages of the first voltage pulse and the second voltage pulse; and a control unit configured to selectively execute (i) a fluctuation-reducing mode in which a control signal is outputted for instructing the third voltage application unit to apply the third voltage and (ii) a data reading mode in which a control signal is outputted for instructing the fourth voltage application unit to apply the fourth voltage after the fluctuation-reducing mode.

Furthermore, a nonvolatile memory device according to an aspect of the present invention is a nonvolatile memory device including a variable resistance nonvolatile memory element which (i) includes a first electrode, a second electrode, and a variable resistance layer which is positioned between the first electrode and the second electrode, comprises a metal oxide, and includes a local region having a degree of oxygen deficiency higher than a degree of oxygen deficiency of a surrounding region of the local region, (ii) has a characteristic that the variable resistance layer changes from a low resistance state to a high resistance state in response to application of a first current pulse between the first electrode and the second electrode, and the variable resistance layer changes from the high resistance state to the low resistance state in response to application of a second current pulse between the first electrode and the second electrode, and (iii) stores data corresponding to the resistance state of the variable resistance layer, the nonvolatile memory device including: a first current application unit configured to apply a third current pulse between the first electrode and the second electrode of the variable resistance layer which has been changed to the resistance state or the low resistance state, the third current pulse having a current with an absolute value smaller than absolute values of currents of the first current pulse and the second current pulse; a second current application unit configured to apply a fourth current pulse between the first electrode and the second electrode of the variable resistance layer which has been changed to the high resistance state or the low resistance state, the fourth current pulse being for reading and having a current with an absolute value smaller than the absolute values of the currents of the first current pulse and the second current pulse; and a control unit configured to selectively execute (i) a fluctuation-reducing mode in which a control signal is outputted for instructing the third current application unit to apply the third current and (ii) a data reading mode in which a control signal is outputted for instructing the fourth current application unit to apply the fourth current after the fluctuation-reducing mode.

### Advantageous Effects of Invention

A method for reading data from a nonvolatile memory element and a nonvolatile memory device according to the present invention make it possible to reduce occurrences of errors in reading data due to an effect of fluctuation.

### BRIEF DESCRIPTION OF DRAWINGS

FIG. 1A is a cross-sectional view showing a configuration of a nonvolatile memory element according to Embodiment 1.

FIG. 1B is a cross-sectional view showing a configuration of the nonvolatile memory element according to Embodiment 1.

FIG. 2 is a diagram for describing a formation of a filament in a variable resistance layer.

FIG. 3 is a circuit configuration diagram of the case where a voltage pulse is applied to the nonvolatile memory element according to Embodiment 1.

FIG. 4 is a diagram showing a change in a resistance value of the nonvolatile memory element according to Embodiment 1.

FIG. 5 is plot of the maximum values and minimum values of the variations in resistance value of the nonvolatile memory element according to Embodiment 1 of the present invention in a high resistance state.

FIG. 6 is a diagram showing a relationship between a current value and normal distribution of the current value when the nonvolatile memory element according to Embodiment 1 is in a high resistance state.

FIG. 7A is a diagram for describing an example of voltage pulse application in a method of reading according to embodiments.

FIG. 7B is a diagram for describing an example of the voltage pulse application in a method of reading according to the embodiments.

FIG. 8A is a diagram for describing another example of the voltage pulse application in a method of reading according to the embodiments.

FIG. 8B is a diagram for describing another example of the voltage pulse application in a method of reading according to the embodiments.

FIG. 9A is a diagram for describing another example of the voltage pulse application in a method of reading according to embodiments.

FIG. 9B is a diagram for describing another example of the voltage pulse application in a method of reading according to the embodiments.

FIG. 10A is a diagram for describing another example of the voltage pulse application in a method of reading according to the embodiments.

FIG. 10B is a diagram for describing another example of the voltage pulse application in a method of reading according to the embodiments.

FIG. 11 is a block diagram showing an example of a configuration of a nonvolatile memory device according to Embodiment 2.

FIG. 12 is a block diagram showing an example of a configuration of a nonvolatile memory device according to Embodiment 3.

FIG. 13A is a cross-sectional view showing a configuration of a nonvolatile memory element forming basis of the present invention.

FIG. 13B is a cross-sectional view showing a configuration of the nonvolatile memory element forming basis of the present invention.

FIG. 14 is a diagram showing a change in resistance value of the nonvolatile memory element forming basis of the present invention.

### DESCRIPTION OF EMBODIMENTS

### Underlying Knowledge Forming Basis of the Present Invention

First before describing embodiments of the present invention, a technique forming basis of the present invention is described.

A variable resistance nonvolatile memory element has a simple structure in which a variable resistance layer is held between a bottom electrode and a top electrode. Then, the variable resistance layer is changed to a high resistance state or a low resistance state by applying, to the variable resistance layer between the top and the bottom electrodes, a predetermined electric pulse having a voltage greater than or equal to a certain threshold value. These different resistance states are associated with data to record information. Since the variable resistance nonvolatile memory element has a simple structure and operation, further miniaturization, increase in capacity, reduction in cost, and so on are expected. Furthermore, the variable resistance nonvolatile memory element may change between a high resistance state and a low resistance state on the order of 100 nanoseconds (ns) or less, and thus draws attention also from the stand point of high-speed operation.

Such nonvolatile memory elements are generally divided into two types depending on a material used for the variable resistance layer (variable resistance material). One of the types is a nonvolatile memory element which is disclosed in Patent Literature 1 and the like and in which a variable resistance material includes a perovskite material (e.g., Pr₍₁₋ₓ₎CaₓMnO₃(PCMO), LaSrMnO₃ (LSMO), GdBaCoₓO_{y} (GBCO)). The other type is a nonvolatile memory element in which a variable resistance material includes a binary transition metal oxide. The binary transition metal oxide has a simple composition and structure in comparison with the above perovskite material, and thus it is easy to perform composition control and film formation in a manufacturing process. The binary transition metal oxide also has relatively favorable compatibility with a semiconductor manufacturing process.

Although much about the physical mechanism of resistance change still remains unknown, as a result of the recent studies, it is believed that a conductive filament (conduction path) is formed in a binary transition metal oxide included in the variable resistance layer, and the change in resistance occurs with a change in defect density in the filament due to oxidation-reduction.

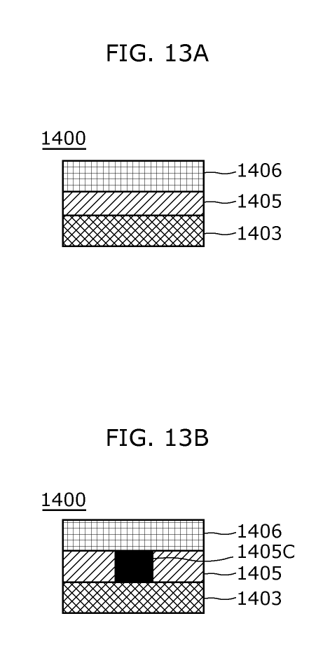

FIG. 13A and FIG. 13B are cross-sectional views showing configurations of a conventional nonvolatile memory element. FIG. 13A shows an ordinary configuration of a nonvolatile memory element 1400 including a first electrode 1403, a second electrode 1406, and a transition metal oxide layer (variable resistance layer) 1405 positioned between the electrodes. In this configuration, a voltage (initial breakdown voltage) is applied between the first electrode 1403 and the second electrode 1406 to form a filament 1405c between the first electrode 1403 and the second electrode 1406 as shown in FIG. 13B. The filament 1405c is equivalent to a current path in which a current density of a current flowing between the first electrode 1403 and the second electrode 1406 is locally high.

In a variable resistance nonvolatile memory element, the resistance value, which is once set, sometimes changes in a long or a short finite time. In general, the phenomenon is known in which, even without new writing operation, the stored information deteriorates due to the stored resistance state gradually changing from the high resistance state to the low resistance state or from the low resistance state to the high resistance state after some considerable time (for example, 100 hours or more) is elapsed.

The inventors found, in addition to such a deterioration of information caused by a gradual change in resistance value over a relatively long period of time (retention characteristic deterioration), a new type of phenomenon regarding a change in resistance value, that is, a resistance value increases or decreases in a short period of time (hereinafter called “fluctuation in resistance value” or simply called “fluctuation”).

However, methods have not previously been proposed which are effective in reducing fluctuation. Thus, an error due to the effect of fluctuation may occur in reading a resistance state.

In view of this, embodiments of the present invention described below provides a method for reading data from a nonvolatile memory element and a nonvolatile memory device which can reduce occurrence of the error in reading due to the effect of fluctuation.

Here, experiments actually performed with respect to the fluctuation in resistance value in the variable resistance nonvolatile memory element will be described. It should be noted that while the following description is intended as an aid in understanding embodiments of the present invention, the following various experimental conditions and the like are not meant to limit the present invention.

In the below, an example of the phenomenon is described. The inventors fabricated a nonvolatile memory element using, as a variable resistance material, Ta oxide which is deficient in oxygen compared to its stoichiometric composition, and operated the nonvolatile memory element by applying an electrical pulse thereto to examine, in detail, how the set resistance value changes over time. Note that, the nonvolatile memory element is a variable resistance nonvolatile memory element having bipolar switching characteristics, which changes to the high resistance state when a positive voltage relative to the bottom electrode is applied to the top electrode and changes to the low resistance state when a negative voltage relative to the bottom electrode is applied to the top electrode.

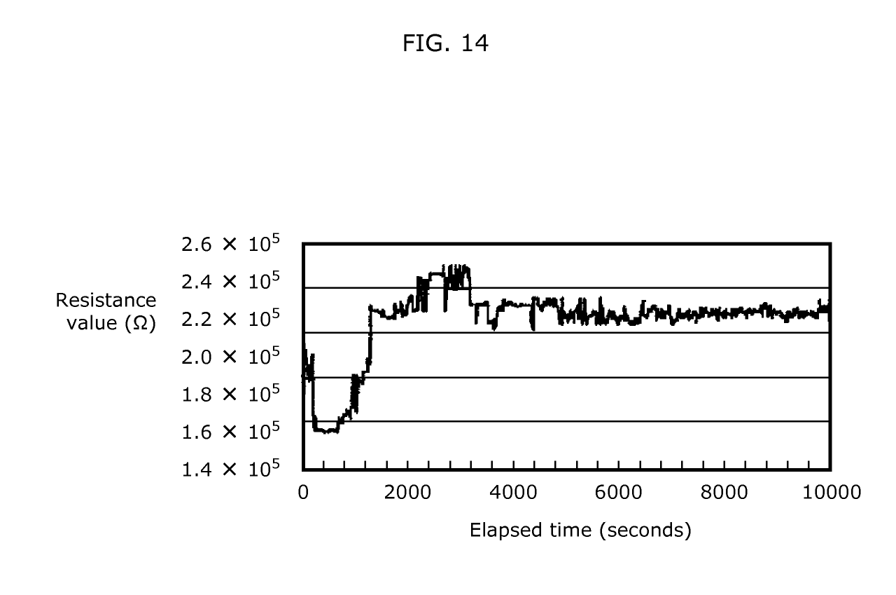

The measurement result is shown in FIG. 14. Herein, the nonvolatile memory element was operated by alternately applying, for 100 times in total, an electrical pulse of +2.5 V for 100 ns and an electrical pulse of −2.0 V for 100 ns to the fabricated nonvolatile memory element connected in series to a load resistance of 6.4 kΩ. Then, the electrical pulse of +2.5 V for 100 ns was applied last, to set the nonvolatile memory element to the high resistance state (approximately 120 kΩ). In this state, the nonvolatile memory element was kept at room temperature and examined as to how the resistance value changes over time.

Referring to FIG. 14, it can be seen that the resistance value of the nonvolatile memory element repeatedly and drastically increases and decreases while the nonvolatile memory element is kept at room temperature and no voltage sufficiently large to cause resistance change is applied thereto. Specifically, the resistance value dramatically drops to approximately 50 kΩ in 200 seconds from the start, and then, the resistance value begins to increase to reach the resistance value of 200 kΩ in 1000 seconds.

As described above, since the initially set resistance value largely increases and decreases in a short time, an error may occur in reading data. Hereinafter, description is given of an example of the nonvolatile memory element having a set resistance value of 120 kΩ whose measurement results is indicated in FIG. 14. Here, assuming that 60 kΩ which is half the set resistance value is a threshold value (data decision point, reference level), the nonvolatile memory element which has the resistance value of 60 kΩ or greater is defined to be in the high resistance state, and the nonvolatile memory element which has the resistance value of less than 60 kΩ is defined to be in the low resistance state. In this case, when the resistance value of the nonvolatile memory element is read approximately 1000 seconds after the resistance value is set, the resistance value is 50 kΩ. Thus, it is determined that the nonvolatile memory element is in a low resistance state. On the other hand, when the resistance value of the nonvolatile memory element is read 2000 seconds after the resistance value is set, the resistance value exceeds 200 kΩ. Thus, it is determined that the nonvolatile memory element is in a high resistance state. As described above, depending on a time at which data is read, a situation is created where data of the same nonvolatile memory element may be “1” or may be “0”.

A similar phenomenon is also reported on a variable resistance nonvolatile memory element including a nickel (Ni) oxide (Daniele lelmini, et al., Appl. Phys. Lett., Vol. 96, 2010, pp. 53503 (NPL 2)).

In view of this, with repeated experiments and considerations, the inventors have devised a data reading method and so on which can reduce the effect of fluctuation and improve the data retention characteristics in the variable resistance nonvolatile memory element. The following describes embodiments of the present invention.

A method for reading data from a variable resistance nonvolatile memory element according to an aspect of the present invention is a method for reading data from a variable resistance nonvolatile memory element which (i) includes a first electrode, a second electrode, and a variable resistance layer which is positioned between the first electrode and the second electrode, comprises a metal oxide, and includes a local region having a degree of oxygen deficiency higher than a degree of oxygen deficiency of a surrounding region of the local region, (ii) has a characteristic that the variable resistance layer changes from a low resistance state to a high resistance state in response to application of a first voltage pulse between the first electrode and the second electrode, and the variable resistance layer changes from the high resistance state to the low resistance state in response to application of a second voltage pulse between the first electrode and the second electrode, and (iii) stores data corresponding to the resistance state of the variable resistance layer, the method including: applying a third voltage pulse between the first electrode and the second electrode of the variable resistance layer which has been changed to the high resistance state or the low resistance state, the third voltage pulse having a voltage with an absolute value smaller than absolute values of voltages of the first voltage pulse and the second voltage pulse; and reading the resistance state of the variable resistance layer by applying a fourth voltage pulse between the first electrode and the second electrode after the applying of a third voltage pulse, the fourth voltage pulse having a voltage with an absolute value smaller than the absolute values of the voltages of the first voltage pulse and the second voltage pulse. Furthermore, a method for reading data from a variable resistance nonvolatile memory element according to an aspect of the present invention is a method for reading data from a variable resistance nonvolatile memory element which (i) includes a first electrode, a second electrode, and a variable resistance layer which is positioned between the first electrode and the second electrode, comprises a metal oxide, and includes a local region having a degree of oxygen deficiency higher than a degree of oxygen deficiency of a surrounding region of the local region, (ii) has a characteristic that the variable resistance layer changes from a low resistance state to a high resistance state in response to application of a first current pulse between the first electrode and the second electrode, and the variable resistance layer changes from the high resistance state to the low resistance state in response to application of a second current pulse between the first electrode and the second electrode, and (iii) stores data corresponding to the resistance state of the variable resistance layer, the method including: applying a third current pulse between the first electrode and the second electrode of the variable resistance layer which has been changed to the high resistance state or the low resistance state, the third current pulse having a current with an absolute value smaller than absolute values of currents of the first current pulse and the second current pulse; and reading the resistance state of the variable resistance layer by applying a fourth current pulse between the first electrode and the second electrode after the applying of a third current pulse, the fourth current pulse having a current with an absolute value smaller than the absolute values of the currents of the first current pulse and the second current pulse. The occurrence of the error in reading data due to the effect of fluctuation can be reduced by applying the third voltage pulse (or the third current pulse), before applying the fourth voltage pulse (or the fourth current pulse) for reading.

Furthermore, it may be that the local region is formed toward the first electrode from the second electrode, the local region being in contact with the second electrode and not in contact with the first electrode.

Furthermore, the variable resistance layer may have a fluctuation characteristic that a resistance value randomly changes over time.

With this, even in the case of a nonvolatile memory element with the local region having a configuration in which fluctuation can easily occur, occurrence of the error in reading due to the effect of fluctuation can be reduced.

Furthermore, it may be that the variable resistance layer includes a first oxide layer and a second oxide layer which has a degree of oxygen deficiency higher than a degree of oxygen deficiency of the first oxide layer, and the local region has a degree of oxygen deficiency higher than the degree of oxygen deficiency of the first oxide layer.

Furthermore, it may be that the first oxide layer is in contact with the second electrode, and the local region is in contact with the second electrode and formed toward the first electrode from the second electrode, the local region penetrating the first oxide layer.

Furthermore, when the reading of the resistance state is repeated a plurality of times in a period after data is stored and before the resistance state of the nonvolatile memory element is changed next, the nonvolatile memory element may execute the applying of a third voltage pulse before each of the plurality of times that the reading of the resistance state is executed. With this, accurate reading can be performed in a stable manner.

Furthermore, the first voltage pulse and the second voltage pulse may be different in polarity. Furthermore, the first current pulse and the second current pulse may be different in polarity. At this time, the nonvolatile memory element is a bipolar driver element. With this, even when the nonvolatile memory element is a bipolar driver element, accurate reading can be performed in a stable manner.

Furthermore, in the applying of a third voltage pulse, the third voltage pulse having the voltage with the absolute value greater than the absolute value of the voltage of the fourth voltage pulse may be applied between the first electrode and the second electrode. Furthermore, in the applying of a third current pulse, the third current pulse having the current with the absolute value greater than the absolute value of the current of the fourth current pulse may be applied between the first electrode and the second electrode. With this, while increasing effects on reducing fluctuation with the third voltage pulse (or the third current pulse), power consumption of the fourth voltage pulse (or the fourth current pulse) for reading can be reduced.

Furthermore, the first voltage pulse and the third voltage pulse may be identical in polarity. Furthermore, the first current pulse and the third current pulse may be identical in polarity. When the third voltage pulse (or the third current pulse) has the polarity identical to the polarity of the first voltage pulse (or the first current pulse), which causes the variable resistance layer to change from the low resistance state to the high resistance state in a normal operation, it is possible to, for example, reduce occurrence of the error in reading data for the downward fluctuation of the resistance value.

Furthermore, the second voltage pulse and the third voltage pulse may be identical in polarity. Furthermore, the second current pulse and the third current pulse may be identical in polarity. When the third voltage pulse (or the third current pulse) has the polarity identical to the polarity of the second voltage pulse (or the second current pulse), which causes the variable resistance layer to change from the high resistance state to the low resistance state in a normal operation, it is possible to, for example, reduce occurrence of the error in reading data for the upward fluctuation of the resistance value.

Furthermore, the metal oxide may be a tantalum oxide. With this, it is possible to achieve a stable resistance change.

A nonvolatile memory device according to an aspect of the present invention is a nonvolatile memory device including a variable resistance nonvolatile memory element which (i) includes a first electrode, a second electrode, and a variable resistance layer which is positioned between the first electrode and the second electrode, comprises a metal oxide, and includes a local region having a degree of oxygen deficiency higher than a degree of oxygen deficiency of a surrounding region of the local region, (ii) has a characteristic that the variable resistance layer changes from a low resistance state to a high resistance state in response to application of a first voltage pulse between the first electrode and the second electrode, and the variable resistance layer changes from the high resistance state to the low resistance state in response to application of a second voltage pulse between the first electrode and the second electrode, and (iii) stores data corresponding to the resistance state of the variable resistance layer, the nonvolatile memory device including: a first voltage application unit configured to apply a third voltage pulse between the first electrode and the second electrode of the variable resistance layer which has been changed to the high resistance state or the low resistance state, the third voltage pulse having a voltage with an absolute value smaller than absolute values of voltages of the first voltage pulse and the second voltage pulse; a second voltage application unit configured to apply a fourth voltage pulse between the first electrode and the second electrode of the variable resistance layer which has been changed to the high resistance state or the low resistance state, the fourth voltage pulse being for reading and having a voltage with an absolute value smaller than the absolute values of the voltages of the first voltage pulse and the second voltage pulse; and a control unit configured to selectively execute (i) a fluctuation-reducing mode in which a control signal is outputted for instructing the third voltage application unit to apply the third voltage and (ii) a data reading mode in which a control signal is outputted for instructing the fourth voltage application unit to apply the fourth voltage after the fluctuation-reducing mode. Furthermore, a nonvolatile memory device according to an aspect of the present invention is a nonvolatile memory device including a variable resistance nonvolatile memory element which (i) includes a first electrode, a second electrode, and a variable resistance layer which is positioned between the first electrode and the second electrode, comprises a metal oxide, and includes a local region having a degree of oxygen deficiency higher than a degree of oxygen deficiency of a surrounding region of the local region, (ii) has a characteristic that the variable resistance layer changes from a low resistance state to a high resistance state in response to application of a first current pulse between the first electrode and the second electrode, and the variable resistance layer changes from the high resistance state to the low resistance state in response to application of a second current pulse between the first electrode and the second electrode, and (iii) stores data corresponding to the resistance state of the variable resistance layer, the nonvolatile memory device including: a first current application unit configured to apply a third current pulse between the first electrode and the second electrode of the variable resistance layer which has been changed to the high resistance state or the low resistance state, the third current pulse having a current with an absolute value smaller than absolute values of currents of the first current pulse and the second current pulse; a second current application unit configured to apply a fourth current pulse between the first electrode and the second electrode of the variable resistance layer which has been changed to the high resistance state or the low resistance state, the fourth current pulse being for reading and having a current with an absolute value smaller than the absolute values of the currents of the first current pulse and the second current pulse; and a control unit configured to selectively execute (i) a fluctuation-reducing mode in which a control signal is outputted for instructing the third current application unit to apply the third current and (ii) a data reading mode in which a control signal is outputted for instructing the fourth current application unit to apply the fourth current after the fluctuation-reducing mode. It is possible to apply, before the data reading mode, the third voltage pulse (or the third current pulse) in the fluctuation-reducing mode, and thus occurrence of the error in reading data due to the effect of fluctuation can be reduced.

Furthermore, it may be that the local region is formed toward the first electrode from the second electrode, the local region being in contact with the second electrode and not in contact with the first electrode.

Furthermore, the variable resistance layer may have a fluctuation characteristic that a resistance value randomly changes over time.

With this, even in the case of a nonvolatile memory element with a local region having a configuration in which fluctuation can easily occur, occurrence of the error in reading due to the effect of fluctuation can be reduced.

Furthermore, when the data reading mode is executed a plurality of times, the control unit may be configured to execute the fluctuation-reducing mode before each of the plurality of times that the data reading mode is executed. With this, accurate reading can be performed in a stable manner.

Furthermore, the first voltage pulse and the second voltage pulse may be different in polarity. Furthermore, the first current pulse and the second current pulse may be different in polarity. At this time, the nonvolatile memory element is a bipolar driver element. With this, even when the nonvolatile memory element is a bipolar driver element, accurate reading can be performed in a stable manner.

Furthermore, it may be that the variable resistance layer includes a first oxide layer and a second oxide layer which has a degree of oxygen deficiency higher than a degree of oxygen deficiency of the first oxide layer, and the first oxide layer includes the local region which has a degree of oxygen deficiency higher than the degree of oxygen deficiency of the first oxide layer. The resistance value of the variable resistance layer can be changed with the change in resistance value in the local region.

Furthermore, it may be that the first oxide layer is in contact with the second electrode, and the local region is in contact with the second electrode and formed toward the first electrode from the second electrode, the local region penetrating the first oxide layer.

Furthermore, the first voltage application unit may be configured to apply the third voltage pulse between the first electrode and the second electrode, the third voltage pulse having the voltage with the absolute value greater than the absolute value of the voltage of the fourth voltage pulse. Furthermore, the first current application unit may be configured to apply the third current pulse between the first electrode and the second electrode, the third current pulse having the current with the absolute value greater than the absolute value of the current of the fourth current pulse. With this, while increasing effects on reducing fluctuation with the third voltage pulse (or the third current pulse), power consumption of the fourth voltage pulse (or the fourth current pulse) for reading can be reduced.

Furthermore, the first voltage pulse and the third voltage pulse may be identical in polarity. Furthermore, the first current pulse and the third current pulse may be identical in polarity. When the third voltage pulse (or the third current pulse) has the polarity identical to the polarity of the first voltage pulse (or the first current pulse), which causes a variable resistance layer to change from the low resistance state to the high resistance state in a normal operation, it is possible to, for example, reduce occurrence of the error in reading data for the downward fluctuation of the resistance value.

Furthermore, the second voltage pulse and the third voltage pulse may be identical in polarity. Furthermore, the second current pulse and the third current pulse may be identical in polarity. When the third voltage pulse (or the third current pulse) has the polarity identical to the polarity of the second voltage pulse (or the second current pulse), which causes a variable resistance layer to change from the high resistance state to the low resistance state in a normal operation, it is possible to, for example, reduce occurrence of the error in reading data for the upward fluctuation of the resistance value.

Furthermore, the metal oxide may be a tantalum oxide. With this, it is possible to achieve a stable resistance change.

Hereinafter, embodiments will be described, with reference to the drawings. It should be noted that each of the following descriptions show a specific example of an embodiment. Thus, values, shapes, materials, structural elements, the arrangement and connection of the structural elements, steps, the processing order of the steps etc. shown in the following embodiments are mere examples, and therefore do not limit the inventive concept. Among the structural elements in the following embodiments, structural elements not recited in any one of the independent claims defining the most generic part of the inventive concept are described as arbitrary components.

The following describes embodiments of the present invention, with reference to drawings.

### Embodiment 1

[Configuration of Nonvolatile Memory Element]

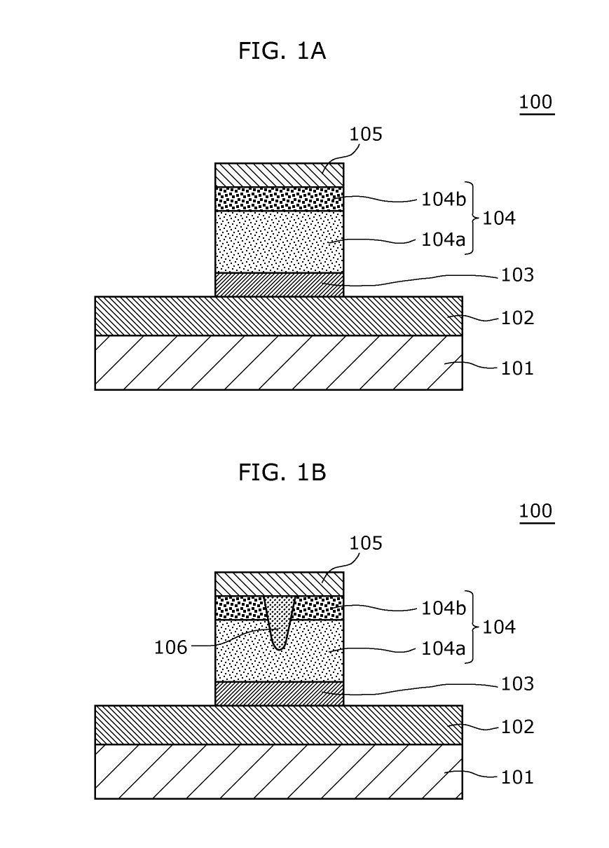

Each of FIG. 1A and FIG. 1B is a cross-sectional view showing a configuration of a nonvolatile memory element according to Embodiment 1.

As shown in FIG. 1A, a nonvolatile memory element 100 according to this embodiment includes a substrate 101, an interlayer dielectric 102 formed on the substrate 101, a first electrode 103 formed on the interlayer dielectric 102, a second electrode 105, and a variable resistance layer 104 positioned between the first electrode 103 and the second electrode 105. In the nonvolatile memory element 100, data is recorded corresponding to the resistance state of the variable resistance layer 104.

The variable resistance layer 104 has a stacked structure including a first oxide layer 104a comprising a first transition metal oxide, and a second oxide layer 104b comprising a second transition metal oxide. In this embodiment, the first oxide layer 104a comprises an oxygen-deficient tantalum oxide, and the second oxide layer 104b also comprises a tantalum oxide. Here, an oxygen content atomic percentage of the second oxide layer 104b is higher than an oxygen content atomic percentage of the first oxide layer 104a. In other words, the first oxide layer 104a has a degree of oxygen deficiency higher than a degree of oxygen deficiency of the second oxide layer 104b. Thus, the resistance value (to be more accurate, resistivity) of the second oxide layer 104b is greater than the resistance value (to be more accurate, resistivity) of the first oxide layer 104a. In this case, an electric field applied to the variable resistance layer 104 is likely to be localized in the second oxide layer 104b. Thus, it is easy to form a structure in which a local region 106 has no contact with the first electrode 103 as shown in FIG. 1B.

More specifically, as shown in FIG. 1B, the variable resistance layer 104 includes the local region 106 in the vicinity of the interface between the first oxide layer 104a and the second oxide layer 104b. The local region 106 has a degree of oxygen deficiency which is higher than the degree of oxygen deficiency of the second oxide layer 104b and is different from the degree of oxygen deficiency of the first oxide layer 104a.

The local region 106 is a region having a higher degree of oxygen deficiency than a surrounding region of the local region 106, and refers to a part of the variable resistance layer 104 in which a current dominantly flows when a voltage is applied between the first electrode 103 and the second electrode 105. More specifically, the local region 106 refers to a region including aggregation of filaments (conduction paths) formed in the variable resistance layer 104. In other words, change in the resistance of the variable resistance layer 104 occurs in the local region 106. Thus, when a driving voltage is applied to the variable resistance layer 104 in the low resistance state, a current dominantly flows in the local region 106 including the filaments. Changing between the high resistance state and the low resistance state occurs in the local region 106 of the variable resistance layer 104.

The local region 106 is formed by applying an initial breakdown voltage to the variable resistance layer 104 including a stacked structure of the first oxide layer 104a and the second oxide layer 104b. The initial breakdown voltage may be a low voltage. With the initial breakdown, as shown in FIG. 1B, the local region 106 is formed which is in contact with the second electrode 105, penetrates through the second oxide layer 104b to cut partway into the first oxide layer 104a, and has no contact with the first electrode 103.

The local region 106 may be a small portion such that the lower end of the local region 106 has no contact with the first electrode 103. Reduction of the local region 106 in size reduces variation in resistance change. However, the local region 106 needs to be large enough to securely include filaments to allow a current to flow.

Furthermore, the variable resistance layer 104 has fluctuation, which refers to a characteristic that the resistance value randomly changes over time. More specifically, the variable resistance layer 104 has, in addition to the above-described degradation (degradation in retention characteristics) of information caused by the resistance value slowly changing over a relatively long time, the fluctuation that is increase or decrease in resistance value in a short time.

Here, a degree of oxygen deficiency refers to the percentage of deficient oxygen with respect to the amount of oxygen comprising an oxide of the stoichiometric composition (in the case where there are plural stoichiometric compositions, the stoichiometric composition having the highest resistance value among the stoichiometric compositions) in the respective transition metal oxides. Compared to a metal oxide with another composition, a metal oxide having a stoichiometric composition is more stable and has a higher resistance value.

For example, in the case of tantalum that is a transition metal as with this embodiment, the oxide having the stoichiometric composition is Ta₂O₅, and thus can be expressed as TaO_{2.5}. The degree of oxygen deficiency of TaO_{2.5} is 0%. For example, the degree of oxygen deficiency of TaO_{1.5} is 40% (=(2.5−1.5)/2.5). The oxygen content atomic percentage of TaO_{2.5} is a ratio of oxygen to the total number of atoms (O/(Ta+O)) and is thus 71.4 atm %. This means that an oxygen-deficient tantalum oxide has an oxygen content atomic percentage higher than 0% and lower than 71.4 atm %. Furthermore, a metal oxide having excess oxygen has a degree of oxygen deficiency with a negative value. In this Description, unless stated otherwise, the degree of oxygen deficiency includes positive values, 0 (zero), and negative values.

When the compositions of the first oxide layer 104a and the second oxide layer 104b are represented by TaOₓ and TaO_{y}, respectively, 0≦x≦2.5 and x<y may be satisfied. Furthermore, 2.1≦y and 0.8≦x≦1.9 may be satisfied to achieve stable resistance change operation. The composition of the metal oxide layer can be measured by the Rutherford Backscattering Spectrometry, for example.

Note that, the variable resistance layer 104 may comprise a metal oxide other than tantalum. Typically, the variable resistance layer 104 comprises a transition metal oxide or an aluminum (Al) oxide. When the variable resistance layer 104 comprises a transition metal oxide, an oxide of a transition metal which is, for example, selected at least one among tantalum (Ta), titanium (Ti), hafnium (Hf), zirconium (Zr), niobium (Nb), tungsten (W), nickel (Ni), or the like, or an aluminum (Al) oxide may be used. A transition metal can take a plurality of oxidation states, and thus different resistance states can be realized by an oxidation-reduction reaction. For example, in the case of using a hafnium oxide, it has been verified that the resistance value of the variable resistance layer can be stably changed at high speed when, in the case where the composition of the first hafnium oxide layer is HfOₓ, x is at least 0.9 and at most 1.6, and when, in the case where the composition of the second hafnium oxide layer is HfO_{y}, y is larger than the value of x. In this case, the thickness of the second hafnium oxide layer may be in the range of approximately 3 nm to 4 nm. Furthermore, in the case of using a zirconium oxide, it has been verified that the resistance value of the variable resistance layer can be stably changed at high speed when, in the case where the composition of the first zirconium oxide layer is ZrOₓ, x is at least 0.9 and at most 1.4, and when, in the case where the composition of the second zirconium oxide layer is ZrO_{y}, y is larger than the value of x. In this case, the thickness of the second zirconium oxide layer may be in the range of approximately 1 nm to 5 nm.

Note that, the first transition metal included in the first oxide layer 104a and the second transition metal included in the second oxide layer 104b may be different transition metals. In this case, the second oxide layer 104b may have a lower degree of oxygen deficiency, that is, a higher resistance, than the first oxide layer 104a. By adopting such a configuration, more of the voltage applied between the first electrode 103 and the second electrode 105 at the time of resistance changing is distributed to the second oxide layer 104b and thus the oxidation-reduction reaction is more facilitated in the second oxide layer 104b. Furthermore, when the first transition metal and the second transition metal comprise different metals, the second transition metal may have a standard electrode potential lower than the standard electrode potential of the first transition metal. This is because it is believed that a resistance change occurs due to an oxidation-reduction reaction which occurs in the local region formed in the second oxide layer 104b having high resistance, causing a change in the filament (conduction path) to change the resistance value of the second oxide layer 104b.

For example, when the first oxide layer 104a comprises an oxygen-deficient tantalum oxide and the second oxide layer 104b comprises a titanium oxide (TiO₂), stable resistance change operation is achieved. Titanium (standard electrode potential=−1.63 eV) is a material that has a lower standard electrode potential than tantalum (standard electrode potential=−0.6 eV). The higher the standard electrode potential of a material is, the more difficult to oxidize the material is. Thus, an oxidation-reduction reactions is more facilitated in the second oxide layer 104b, when the second oxide layer 104b comprises an oxide of a metal having a lower standard electrode potential than the first oxide layer 104a. In another possible combination, aluminum oxide (Al₂O₃) may be included in a high-concentration oxide layer 522 that is a layer which can achieve high resistance. For example, a low-concentration oxide layer 521 may comprise an oxygen-deficient tantalum oxide (TaOₓ) and the high-concentration oxide layer 522 may comprise an aluminum oxide (Al₂O₃).

The second electrode 105 connected to the second oxide layer 104b which has a lower degree of oxygen deficiency may comprise a material, such as platinum (pt), iridium (Ir), or the like, which has a higher standard electrode potential compared to a material included in the second oxide layer 104b and the first electrode 103. In the above configuration, an oxidation-reduction reaction selectively occurs in the second oxide layer 104b near the interface between the second electrode 105 and the second oxide layer 104b, and thereby stable resistance change is achieved.

The second oxide layer 104b may have a dielectric constant higher than the dielectric constant of the first oxide layer 104a. Furthermore, the second oxide layer 104b may have a band gap smaller than the band gap of the first oxide layer 104a. For example, TiO₂ (relative dielectric constant=95, bandgap=3.1 eV) has a higher relative dielectric constant and a smaller band gap than Ta₂O₅ (relative dielectric constant=26, bandgap=4.4 eV). Generally, a material having a higher relative dielectric constant can be more easily broken down than a material having a lower relative dielectric constant, and a material having a smaller band gap can be more easily broken down than a material having a larger band gap. Thus, an initial breakdown voltage can be lowered.

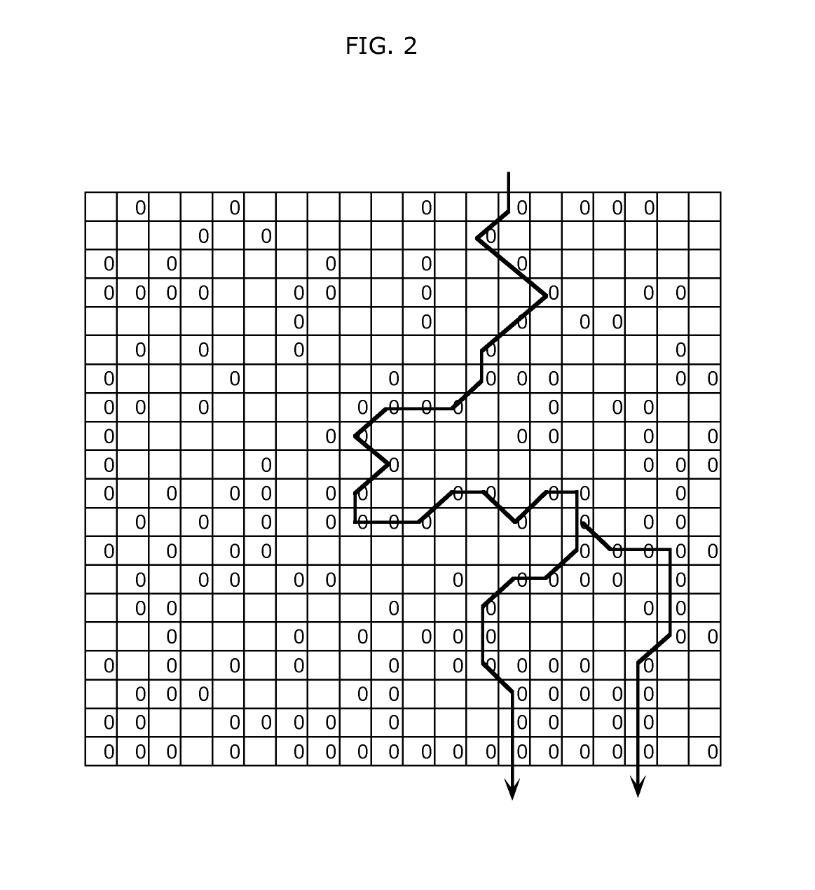

Initial breakdown voltage can be lowered when a transition metal oxide satisfying either or both of the above conditions is included in the second oxide layer 104b to make the breakdown strength of the second oxide layer 104b lower than the breakdown strength of the first oxide layer 104a. This is because the breakdown strength and the dielectric constant of the oxide layer are correlative such that the higher the dielectric constant is, the lower the breakdown strength is as shown in FIG. 1 in J. McPherson et al., IEDM 2002, pp. 633-636 (NPL 3), for example. This is also because the breakdown strength and the band gap of the oxide layer are correlative such that the larger the band gap is, the higher the breakdown strength is, as shown in FIG. 2 of NPL 3.

FIG. 2 illustrates an example of formation of the aforementioned filament by showing a result of simulation using a percolation model. It is assumed here that oxygen-defect sites in the variable resistance layer 104 (especially in a local region in the second oxide layer 104b) connect to each other to form a filament. The percolation model is based on a theory that when oxygen-defect sites (hereinafter simply referred to as defect sites) are randomly distributed in the variable resistance layer 104 and the density of the defect sites or the like exceeds a threshold, a connection between the defect sites is formed with an increased probability. Here, the “defect” means lack of oxygen of the transition metal oxide, and the “density of defect sites” corresponds to the degree of oxygen deficiency. More specifically, the higher the degree of oxygen deficiency is, the higher the density of defect sites is.

In this model, approximate sites of oxygen ions in the variable resistance layer 104 are assumed as sections (sites) in a lattice, and filaments formed by connections of stochastically-formed defect sites are simulated. The sites including “0” in FIG. 2 represents defect sites formed in the variable resistance layer 104. On the other hand, blank sites represent sites occupied by oxygen ions and having a high resistance. The cluster of defect sites (aggregation of mutually connected defect sites) indicated by arrows represents a filament, that is, a current path formed in the variable resistance layer 104 by applying a voltage in the top-bottom direction of the diagram. As shown in FIG. 2, the filament which allows a current to flow between the upper surface and the lower surface of the variable resistance layer 104 includes a cluster of the defect sites which connects the top end and the bottom end of the defect sites among the randomly distributed defect sites. According to the percolation model, the number and the shape of the filaments are stochastically determined. Distributions of the number and the shape of the filaments correspond to variation in a resistance value of the variable resistance layer 104.

[Method for Manufacturing Nonvolatile Memory Element]

Next, a method for manufacturing the nonvolatile memory element 100 according to this embodiment will be described. Noted that, steps, materials, film thicknesses, and other conditions in each processing described below are merely illustrative, and this embodiment is not limited thereto.

First, the interlayer dielectric 102 having a thickness of 200 nm is formed on the substrate 101 which is of single-crystal silicon by a thermal oxidation method. Then, a Pt thin film having a thickness of 100 nm is formed as the first electrode 103 on the interlayer dielectric 102 by sputtering. Note that, a barrier layer or an adhesion layer comprising Ti, TiN, or the like may be formed between the first electrode 103 and the interlayer dielectric 102 by sputtering. After this, the first oxide layer 104a, which is oxygen-deficient, is formed on the first electrode 103 by reactive sputtering using, for example, a Ta target.

Next, the second oxide layer 104b having a lower degree of oxygen deficiency than the first oxide layer 104a is formed on the surface of the first oxide layer 104a by, for example, oxidatively reforming the surface of the first oxide layer 104a or by reactive sputtering using a Ta target. The variable resistance layer 104 includes a stacked structure of the first oxide layer 104a and the second oxide layer 104b.

The thickness of the second oxide layer 104b may be less than or equal to approximately 8 nm to appropriately reduce the initial resistance value. Furthermore, the thickness of the second oxide layer 104b may be greater than or equal to approximately 1 nm to achieve a stable resistance change. For example, the second oxide layer 104b has a thickness of 6 nm.

Next, for example, a Pt thin film having a thickness of 150 nm is formed as the second electrode 105 on the second oxide layer 104b by sputtering.

Thus, the nonvolatile memory element 100 can be fabricated in which the variable resistance layer 104 comprising an oxygen-deficient Ta oxide is positioned between the first electrode 103 and the second electrode 105.

Initial breakdown processing is further performed on the thus fabricated nonvolatile memory element 100, when the variable resistance layer 104 has a high resistance value. Typically, the initial breakdown processing is performed when the second oxide layer 104b is an insulating layer or a semiconductor layer having a significantly high resistance value. In the initial breakdown processing, an initial voltage pulse is applied between the first electrode 103 and the second electrode 105 to change the variable resistance layer 104 from an initial state to a different state. With this, it is believed that a local region including a conduction path (a filament) is formed in a part of a region having a high resistance value in the variable resistance layer 104. For example, when the variable resistance layer 104 includes the first oxide layer 104a and the second oxide layer 104b, the local region having a higher degree of oxygen deficiency than the second oxide layer is included in the second oxide layer. Note that, typically, the local region includes aggregation of a plurality of filaments.

Furthermore, the “initial state” herein refers to a state between right after the manufacturing of the nonvolatile memory element 100 and before the application of a voltage pulse which changes the resistance state of the nonvolatile memory element 100. Furthermore, the “initial resistance value” means the resistance value of the initial state. Note that, an absolute value of a voltage of the initial voltage pulse may be greater than an absolute value of a voltage pulse for a normal writing voltage.

[Resistance Value Fluctuation Phenomenon and its Characteristics]

Hereinafter, the knowledge newly found by the inventors through experiments with respect to the retention characteristics of the resistance state of the nonvolatile memory element 100 fabricated as described above will be described in detail. It should be noted that voltage values, pulse widths, the number of times voltages are applied, resistance values, and the like described below merely show an experimental example describing the knowledge, and this embodiment is not limited thereto.

<Resistance Value Setting>

The resistance change was caused by applying an electrical pulse signal between the first electrode 103 and the second electrode 105 of the nonvolatile memory element 100. The following will describe a case where a voltage pulse is used as the electrical pulse signal. Note that, in this Description, the polarity of the voltage is represented relative to the first electrode 103. In other words, a voltage where a high voltage relative to the first electrode 103 is applied to the second electrode 105 is “positive,” and a voltage where a low voltage relative to the first electrode 103 is applied to the second electrode 105 is “negative”. The nonvolatile memory element 100 changes to the high resistance state when the positive voltage is applied, and changes to the low resistance state when the negative voltage is applied. Note that, in this Description, the “positive polarity” can also be read as a “same polarity as a voltage which changes the nonvolatile memory element to a high resistance state (high resistance writing voltage)”, and the “negative polarity” can also be read as a “same polarity as a voltage which changes the nonvolatile memory element to a low resistance state (low resistance writing voltage)”.

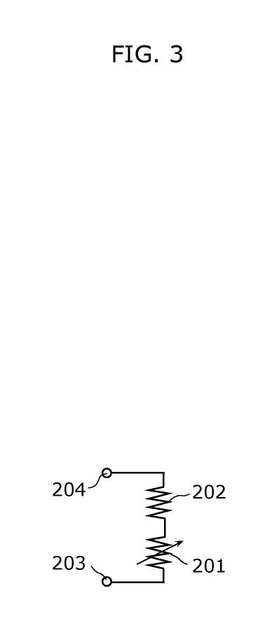

In this experimental example, as shown in FIG. 3, a voltage was applied to a variable resistance nonvolatile memory element 201 (corresponding to the nonvolatile memory element 100 described above) connected in series to load resistance 202 of various values from 0 to 6.4 kΩ. Specifically, voltage pulses which have duration (a pulse width) of 100 ns and the magnitude of +2.5 V and −2.0 V were alternately applied 100 times to a terminal 203 and a terminal 204 shown in FIG. 2.

There are two reasons why the load resistance 202 is connected as described above to the nonvolatile memory element 201. The first reason is that connecting the load resistance 202 changes the set resistance value of the nonvolatile memory element 201, allowing information over a wide resistance range to be obtained. In a sample used in this embodiment, the nonvolatile memory element 201 has a characteristic in which a low resistance value is equal to a value of the load resistance 202, and, in many cases, a high resistance value is approximately 10 to 100 times greater than the low resistance value. Thus, the smaller the load resistance 202 is, the smaller the set resistance value of the nonvolatile memory element 201 is. In contrast, the greater the load resistance 202 is, the greater the set resistance value of the nonvolatile memory element 201 is.

The second reason is that a fluctuation phenomenon in resistance value when the nonvolatile memory element 201 is in actual use is intended to be grasped. In use, the variable resistance nonvolatile memory element is not solely used but is used in a state being connected to a transistor and a diode having certain amounts of resistance values. In addition, there is a resistance from the lines which cannot be considered to be small. Thus, the load resistance 202 was connected, assuming these external load resistances which occur when the variable resistance nonvolatile memory element is in use.

As described above, the resistance value of the nonvolatile memory element 201 was set to the high resistance state (the resistance value RH) and the low resistance state (the resistance value RL). To set the nonvolatile memory element 201 to the high resistance state, voltage pulses of +2.5 V and −2.0 B were alternately applied to the nonvolatile memory element 201 100 times, and last, the voltage pulse of +2.5 V was applied one time. On the other hand, to set the nonvolatile memory element 201 to the low resistance state, the voltage pulse of −2.0 V was last applied one time. Here, the pulse width was in both cases 100 ns.

<Measurement of Short-Time Variation of Resistance Value>

The nonvolatile memory element 201 whose resistance value is set as described above was kept at room temperature and a voltage of 50 mV was applied every 20 seconds to measure the resistance value of the nonvolatile memory element 201. Note that, with such a low voltage of the order of 50 mV, the resistance value of the nonvolatile memory element 201 is not changed.

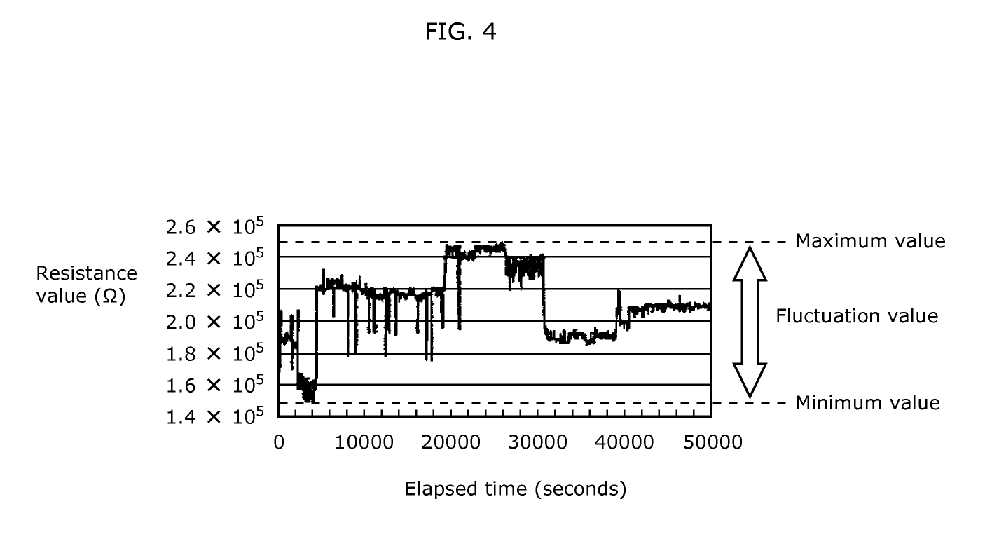

FIG. 4 is a diagram showing variations of the resistance value of the nonvolatile memory element 201 from 0 to 50000 seconds, after the nonvolatile memory element 201 is connected to the load resistance of 6.4 kΩ and then set to the high resistance state. Hereinafter, the resistance value of the nonvolatile memory element 201 immediately after the nonvolatile memory element 201 is set to the high resistance state will be referred to as the set resistance value. In an example shown in FIG. 4, the set resistance value was approximately 170 kΩ. Referring to FIG. 4, the resistance value increases and decreases over time, showing the fluctuation phenomenon. Specifically, the resistance value is a minimum of 150 kΩ approximately 2000 seconds after start of the measurement, and is a maximum of 250 kΩ approximately 20000 seconds after the start.

Note that, although FIG. 4 shows the variations in resistance value after the nonvolatile memory element 201 is set to the high resistance state, the inventors also observed similar variations (fluctuation) in resistance value when the nonvolatile memory element 201 is set to the low resistance state.

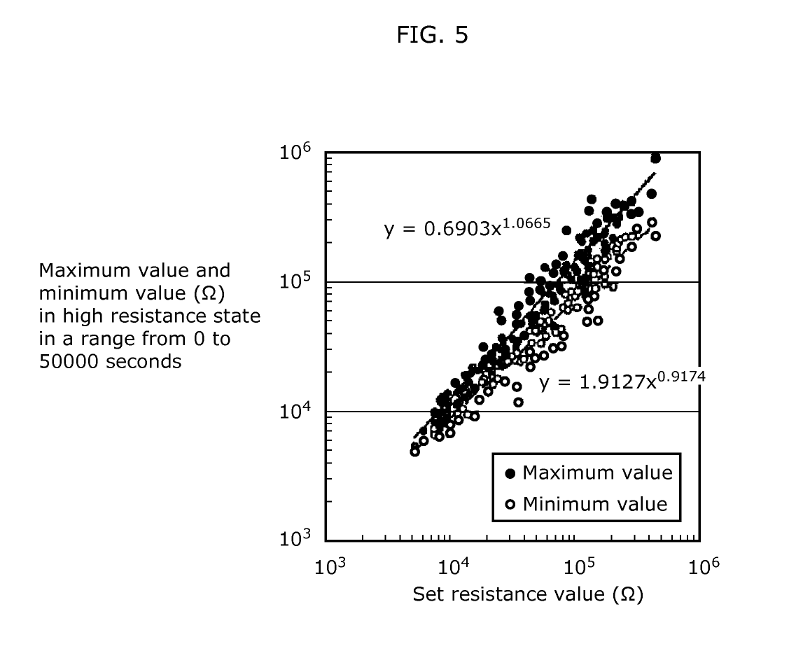

A similar measurement as the above was conducted on a plurality of elements by connecting the elements with the load resistance of 0Ω (no load), 1700Ω, 2150Ω, 3850Ω, 4250Ω, and 6400Ω. The results are summarized in FIG. 5. In FIG. 5, the horizontal axis indicates the set (initial) resistance value of the nonvolatile memory element 201. The vertical axis indicates the maximum value and the minimum value of the resistance value of the nonvolatile memory element 201 that varied in a period from 0 to 50000 seconds after the nonvolatile memory element 201 is set to the high resistance state. Regarding the vertical axis and the horizontal axis, for example, “1.E+03 (Ω)” means “10³ (Ω)” that is 1 kΩ, and “1.E+06 (Ω)” means “10⁶ (Ω)” that is 1 MΩ. Here, data indicated by solid black circles indicates the maximum value of the resistance value, and data indicated by open circle indicates the minimum value of the resistance value. Results of fitting the data by the least square method are also indicated. The solid line shows the result of fitting the maximum values of the resistance value, and the dashed line shows the result of fitting the minimum values of the resistance value.

Referring to FIG. 5, for example, when the set resistance value was 100 kΩ, it can be seen that the resistance value changes from approximately 80 kΩ to approximately 200 kΩ on average (from the fitting line) due to fluctuation in resistance value. In the diagram, a relation (approximation) obtained by fitting is also shown. In the relation, x represents a set resistance value and y represents a maximum value or a minimum value of the resistance value.

<Reduction of Fluctuation>

As described above, it is believed that the a minute filament is formed in the variable resistance layer 104 and an oxidation-reduction reaction occurs in the minute filament to change the resistance value of the variable resistance layer 104, and thus the resistance change phenomenon occurs. Thus, it is believed that the fluctuation phenomenon found by the inventors in this experiment is also caused by the conduction state in the minute filament being changed due to some effect. Specifically, it is believed that the fluctuations may be caused by an incomplete bond or detachment of oxygen atoms. It is also believed that electric potential may be changed and the resistance state may be fluctuated by electrons being captured or released by dangling bonds present in the minute filament. Thus, to a greater or lesser extent, it is inferred that the fluctuation phenomenon unavoidably occurs if the variable resistance nonvolatile memory element is configured to increase or decrease the resistance value in relation to the minute filament.

Based on the above knowledge, the inventors have newly found the following nature of the fluctuation phenomenon.

When the fluctuation phenomenon is caused by electrons being captured or released by dangling bonds present in the minute filament, an amount of fluctuation in resistance value can be reduced by intentionally capturing and releasing the electrons. Specifically, it is believed that it is possible to cause dangling bonds in the filament to capture the electrons, by applying a negative polarity voltage pulse between the electrodes to inject electrons into a filament. When the conduction path (filament) is blocked with this, the resistance value increases. On the other hand, it is believed that it is possible to cause the filament to release the electrons, by applying a positive polarity voltage pulse between the electrodes. When the conduction path (filament) is restored with this, the resistance value decreases. Thus, it becomes possible to reduce an amount of fluctuation, by injecting electrons to a filament or causing the filament to release electrons to change a resistance value in a direction opposite to the direction of fluctuation of the resistance value. In other words, it is believed that the amount of fluctuation can be reduced by causing a change to increase the resistance value for a fluctuation phenomenon where the resistance value decreases, and causing a change to decrease the resistance value for a fluctuation phenomenon where the resistance value increases.

In the following, the above-described voltage pulse for reducing the amount of fluctuation is referred to as a “fluctuation-reducing voltage pulse”. Note that, the “fluctuation-reducing voltage pulse” means a voltage pulse which can reduce, when fluctuation is present, the amount of fluctuation.

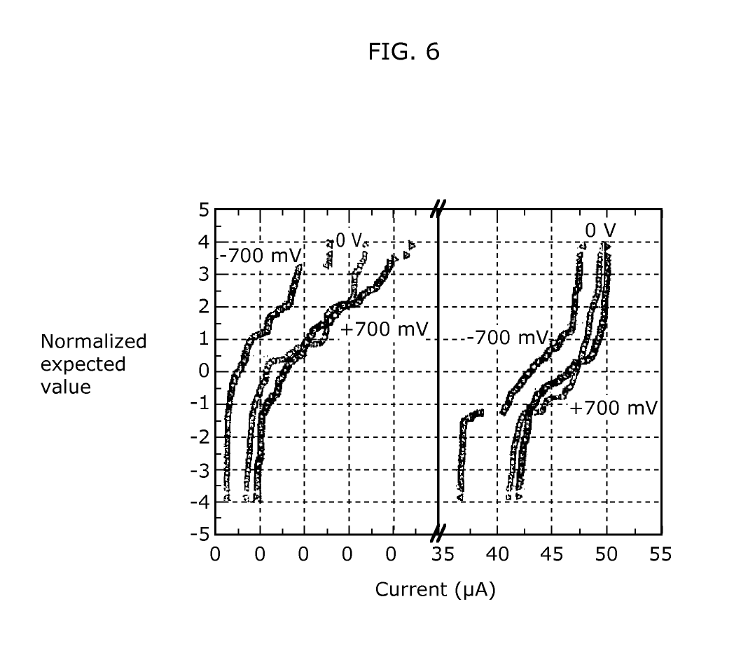

FIG. 6 shows an example in which the resistance value changes due to the fluctuation-reducing voltage pulse. The left of FIG. 6 is a diagram showing the relationship between a current value and normal distribution of the current value obtained by setting the nonvolatile memory elements 100 to the high resistance states, followed by applying the fluctuation-reducing voltage pulses of different voltages (+700 mV, 0 V, and −700 mV) to the nonvolatile memory elements 100, and then performing a reading process. The right of FIG. 6 is a diagram showing the relationship between a current value and normal distribution of the current value obtained by setting the nonvolatile memory elements 100 to the low resistance states, followed by applying the fluctuation-reducing voltage pulses of different voltages (+700 mV, 0 V, and −700 mV) to the nonvolatile memory elements 100, and then performing the reading process. Here, a voltage pulse of +2.5 V for 200 ns for high resistance writing was used to set the nonvolatile memory element 100 to the high resistance state, and a voltage pulse of −1.5 V for 200 ns for low resistance writing was used to set the nonvolatile memory element 100 to the low resistance state. Moreover, a voltage pulse of +700 mV for 200 ns was used as the fluctuation-reducing voltage pulse for reducing the resistance value, and a voltage pulse of −700 mV for 200 ns was used as the fluctuation-reducing voltage pulse for increasing the resistance value.

FIG. 6 also shows a case, as comparison, where the reading process was performed without application of the fluctuation-reducing voltage pulse (sets of plots labeled “0 V” in the diagram). Referring to FIG. 6, it can be seen that the current value is increased (i.e., the resistance value of the nonvolatile memory element 100 is decreased) with application of the fluctuation-reducing voltage pulse of +700 mV in both cases where the nonvolatile memory element 100 is in the high resistance state and in the low resistance state. Moreover, it can be seen that the current value is decreased (i.e., the resistance value of the nonvolatile memory element 100 is increased) with application of the fluctuation-reducing voltage pulse of −700 mV in both cases where the nonvolatile memory element 100 is in the high resistance state and in the low resistance state. In this manner, using the fluctuation-reducing voltage pulse can vary the resistance value of the nonvolatile memory element.

With the above-described characteristics, application of the fluctuation-reducing voltage pulse before the performance of a reading process makes it possible to vary a resistance value in a direction opposite to a direction of the fluctuation of the resistance value. Thus, the amount of fluctuation can be reduced. As a result, the error in reading data or the like due to the effect of fluctuation can be reduced.

<Polarity of Fluctuation-Reducing Voltage Pulse>

As described above, use of the fluctuation-reducing voltage pulse of positive polarity makes it possible to reduce resistance value for the upward fluctuation of the resistance value. On the other hand, use of the fluctuation-reducing voltage pulse of negative polarity makes it possible to increase resistance value for the downward fluctuation of the resistance value.

The polarity of the fluctuation-reducing voltage pulse may be set based on in which state of the nonvolatile memory element, out of the high resistance state and the low resistance state, the fluctuation is more likely to occur. In addition, it is believed that in which state the fluctuation is more likely to occur has correlation with a size of a diameter of the filament formed in the variable resistance layer of the nonvolatile memory element. In general, the larger a diameter of a filament is, the smaller the set resistance value is, and the smaller a diameter of a filament is, the greater the set resistance value is.

When the filament has a large diameter, downward fluctuation of the resistance value in the high resistance state tends to be significant. On the other hand, when the filament has a small diameter, upward fluctuation of the resistance value in the low resistance state tends to be significant. Thus, for the nonvolatile memory element including a filament of a relatively large diameter, the fluctuation-reducing voltage pulse of negative polarity may be used to increase the resistance value. On the other hand, for the nonvolatile memory element including a filament of a relatively small diameter, the fluctuation-reducing voltage pulse of positive polarity may be used to decrease the resistance value. For example, when a nonvolatile memory element including a filament of a small diameter is formed to reduce power consumption or the like, the fluctuation-reducing voltage pulse of positive polarity may be used. In this manner, the polarity of the reducing voltage pulse may be set according to a diameter of a filament.

Furthermore, the fluctuation characteristic is also affected by a condition of writing. For example, when an absolute value of a voltage, a pulse width, the number of pulses, or the like of a voltage pulse for high resistance writing is small compared to a voltage pulse for low resistance writing, downward fluctuation of the resistance value in the high resistance state is significant. Thus, in this case, the fluctuation-reducing voltage pulse of negative polarity may be used to increase the resistance value. On the other hand, when an absolute value of a voltage, a pulse width, the number of pulses, or the like of a voltage pulse for low resistance writing is small compared to a voltage pulse for high resistance writing, upward fluctuation of the resistance value in a low resistance state is significant. Thus, in this case, the fluctuation-reducing voltage pulse of positive polarity may be used to decrease the resistance value.

[Method for Reading Data from Nonvolatile Memory Element]

After data is written to the nonvolatile memory element, an error may occur in reading data due to a significant change in the resistance value from the set resistance value caused by the fluctuation phenomenon. In order to avoid such inconvenience, in this embodiment, the nonvolatile memory element (i) includes the first electrode, the second electrode, and the variable resistance layer which is positioned between the first electrode and the second electrode, comprises a metal oxide, and includes a local region having a degree of oxygen deficiency higher than a degree of oxygen deficiency of a surrounding region of the local region, (ii) has a characteristic that the variable resistance layer changes from the low resistance state to the high resistance state in response to application of a first voltage pulse between the first electrode and the second electrode, and the variable resistance layer changes from the high resistance state to the low resistance state in response to application of a second voltage pulse between the first electrode and the second electrode, and (iii) stores data corresponding to the resistance state of the variable resistance layer, and a method for reading data from the nonvolatile memory element includes: applying a third voltage pulse between the first electrode and the second electrode of the variable resistance layer which has been changed to the high resistance state or the low resistance state, the third voltage pulse having a voltage with an absolute value smaller than absolute values of voltages of the first voltage pulse and the second voltage pulse; and reading the resistance state of the variable resistance layer by applying a fourth voltage pulse between the first electrode and the second electrode after the applying of a third voltage pulse, the fourth voltage pulse having a voltage with an absolute value smaller than the absolute values of the voltages of the first voltage pulse and the second voltage pulse.

The following describes in particular a process of reducing a fluctuation and a process of reading in the method for reading data from the nonvolatile memory element 100, according to this embodiment. Note that, in an example described below, it is assumed that an initial breakdown voltage is applied to the nonvolatile memory element 100 and, as a result, a filament is formed in the variable resistance layer 104, prior to the performance of a data reading method. Furthermore, in the below, an HR writing voltage, an LR writing voltage, a fluctuation-reducing pulse, and a reading voltage is an example of a first voltage pulse, a second voltage pulse, a third voltage pulse, and a fourth voltage pulse, respectively.

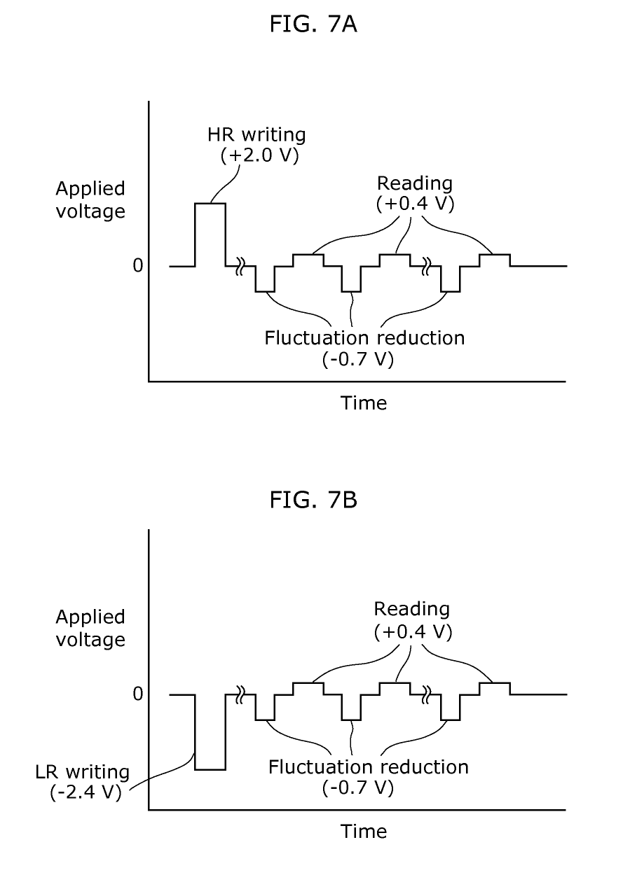

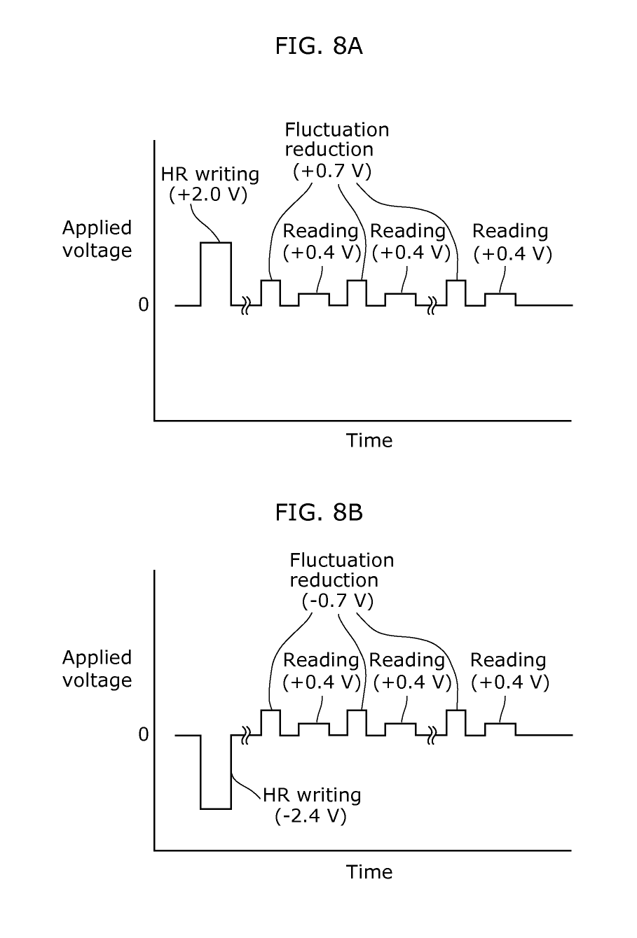

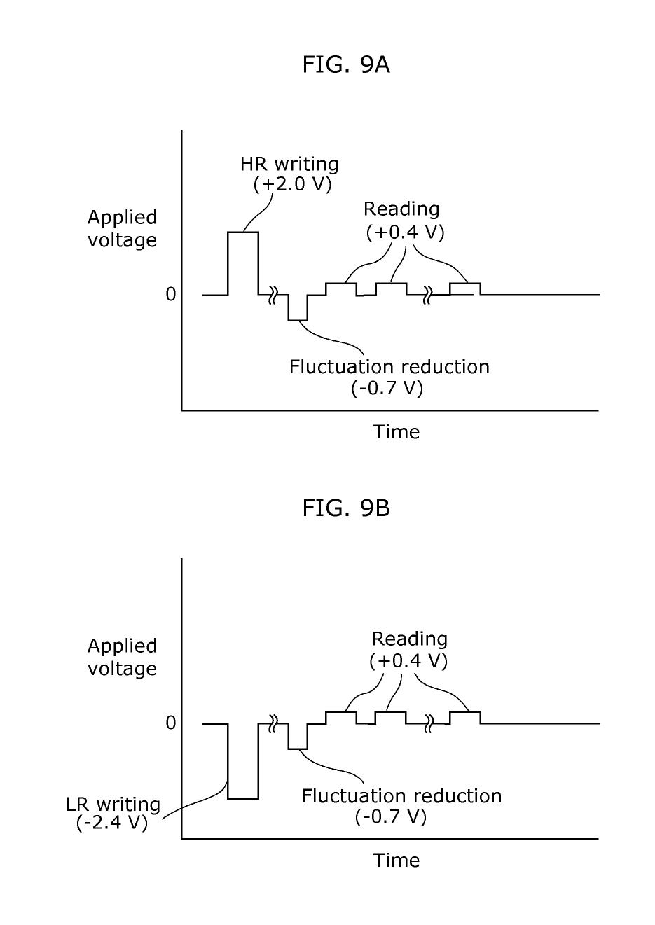

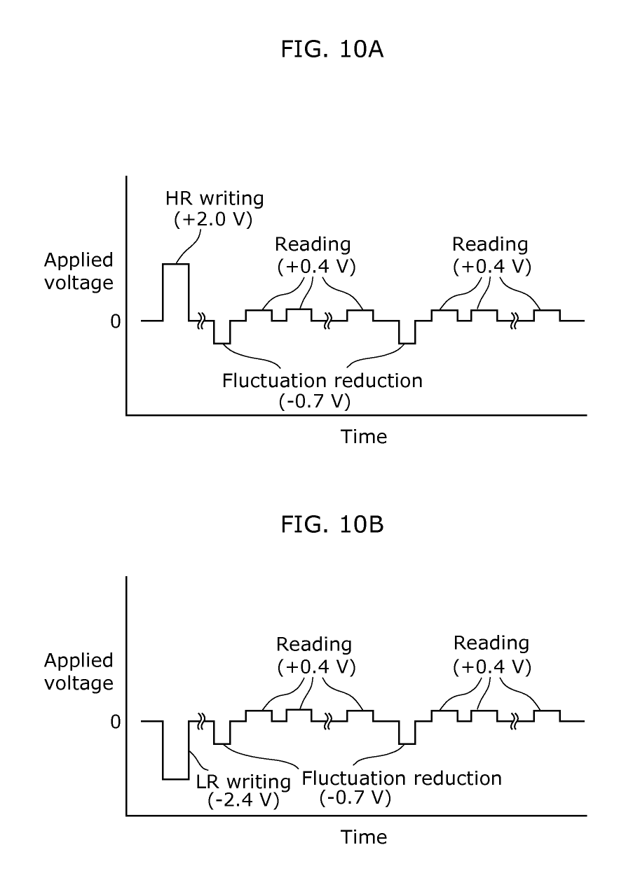

Each of FIG. 7A to FIG. 10B is a diagram for describing an example of voltage pulse application in a reading method according to this embodiment. In FIG. 7A to FIG. 10B, each of FIG. 7A, FIG. 8A, FIG. 9A, and FIG. 10A schematically shows a waveform of an application voltage of the case in which the HR writing (high resistance writing) is performed and then a plurality of reading is performed, and each of FIG. 7B, FIG. 8B, FIG. 9B, and FIG. 10B schematically shows a waveform of an application voltage of the case in which the LR writing (low resistance writing) is performed and then a plurality of reading is performed. Note that, the voltage value indicated in each of FIG. 7A to FIG. 10B is merely an example.

Each of FIG. 7A and FIG. 7B shows an example of a nonvolatile memory element on which the HR writing is performed with a writing voltage of +2.0V or the LR writing is performed with a writing voltage of −2.4V. To the nonvolatile memory element, the fluctuation-reducing voltage pulse of negative polarity having a voltage with an absolute value smaller than an absolute value of the HR writing voltage is applied between the electrodes before each time data is read using a reading voltage of +0.4 V. Usage of the fluctuation-reducing voltage pulse of negative polarity before application of a reading voltage as described makes it possible to increase the resistance value of the nonvolatile memory element. Thus, this reading operation may be employed by a nonvolatile memory element in which a filament has a relatively large diameter or density of defect sites is relatively high and which tends to show decrease in resistance value due to the fluctuation.

In examples shown in FIG. 8A and FIG. 8B, different from examples shown in FIG. 7A and FIG. 7B, the fluctuation-reducing voltage pulse of positive polarity is used before an application of a reading voltage. This can reduce the resistance value of the nonvolatile memory element. Thus, this reading operation may be employed by a nonvolatile memory element in which a filament has a relatively small diameter or density of defect sites is low and which tends to show increase in resistance due to the fluctuation.

As described above, FIG. 7A and FIG. 7B, and FIG. 8A and FIG. 8B show examples in which the fluctuation-reducing voltage pulse is applied before each application of a voltage for reading data. In this case, the effect of fluctuation can be reduced for every reading process, and thus it is possible to realize accurate reading in a stable manner. Furthermore, since the reading is performed immediately after the application of the fluctuation-reducing voltage pulse, it is possible to realize accurate reading in a stable manner even in the case where the resistance value changes over time after the application of the fluctuation-reducing voltage pulse.

Furthermore, as shown in FIG. 9A and FIG. 9B, when the reading process is repeatedly performed for a plurality of times after the HR writing or the LR writing is performed, the application of the fluctuation-reducing voltage pulse may be performed only before the reading process that is performed for the first time. In this case, it is possible to reduce increase in the consumption of an electric current compared to the case in which the fluctuation-reducing voltage pulse is applied each time the reading process is performed.

Other than the above-described operations, that is, the fluctuation-reducing voltage pulse is applied each time the reading process is performed or the fluctuation-reducing voltage pulse is applied only before the reading process that is performed for the first time, for example, as shown in FIG. 10A and FIG. 10B, the fluctuation-reducing voltage pulse may be applied for every specific period of time, and a reading process may be executed a plurality of times in the specific period. In this case, it is possible to realize reading of data in a stable manner while reducing an increase in the consumption of an electric current in a reading process.

Furthermore, although each of FIG. 7A to FIG. 10B describes a case in which a reading process is performed a plurality of times in a period after a writing is performed and before a writing is performed next, the data reading method according to this embodiment is not limited to this case. When the fluctuation-reducing voltage pulse and the reading voltage pulse are applied in the stated order once or more in a period after the application of a writing voltage pulse and before the application of the writing voltage pulse next, the effect of fluctuation reduction can be at least produced.

Note that, in the case of a nonvolatile memory device including a plurality of nonvolatile memory elements, what is called a block read may be performed in which reading is performed on a memory block basis including a predetermined number of nonvolatile memory elements. In this case, it becomes possible to realize a high speed reading in a stable manner, by applying the fluctuation-reducing voltage pulse to all of the nonvolatile memory elements included in the memory block prior to execution of the block read, and then executing the block read.

As described above, application of the fluctuation-reducing voltage pulse makes it possible to reduce the error in reading data due to the effect of fluctuation.

[Voltage Value of Fluctuation-Reducing Voltage Pulse]

The following describes an example of a range of the voltage value of the fluctuation-reducing voltage pulse.

In the above-described examples, the writing voltage pulses of +2.0 V and −2.4 V are used as a voltage pulse for HR writing and a voltage pulse for LR writing, respectively, and a voltage pulse of +0.7 V or −0.7 V is used as the fluctuation-reducing voltage pulse. In this manner, an absolute value of a voltage of the fluctuation-reducing voltage pulse needs to be smaller than at least an absolute value of a voltage of the writing voltage pulse. This is for preventing the nonvolatile memory element from changing the resistance state, from high to low or low to high, due to application of the fluctuation-reducing voltage pulse. In view of this, the fluctuation-reducing voltage pulse may be set to a voltage with an absolute value smaller than an absolute value of a voltage that is necessary for the nonvolatile memory element to change the resistance state, from high to low or low to high.

Furthermore, in an example described above, a voltage pulse of +0.4V is used as a reading voltage pulse. As described, when the reading voltage pulse and the fluctuation-reducing voltage pulse are compared to each other, the fluctuation-reducing voltage pulse may have a voltage with an absolute value greater than an absolute value of a voltage of the reading voltage pulse. Even when the voltage of the fluctuation-reducing voltage pulse is small in absolute value, it is possible to produce advantageous effects of reduction in the amount of fluctuation by increasing a pulse width. However, a pulse width may be small in order to realize a reading operation at high speed. In view of the above, the fluctuation-reducing voltage pulse may be set to a voltage with an absolute value greater than an absolute value of a voltage of the reading voltage pulse.

Note that, although a voltage pulse is applied to reduce the fluctuation in the above-described embodiment, similar advantageous effects are produced with application of a current pulse.

As described above, it is believed that the fluctuation phenomenon is caused by electrons being captured or released by dangling bonds present in the minute filament. In the above-described embodiments, the fluctuation of a resistance value of the variable resistance element is reduced by intentionally capturing and releasing the electrons. Although the above embodiment described an example in which a voltage pulse of negative polarity is applied between the electrodes to inject an electron into a filament to cause a dangling bond in a filament to capture an electron, an electron can be injected to a filament in a similar manner with a current pulse as well.

### Embodiment 2

Embodiment 2 is a 1 transistor/1 resistance (1T1R) nonvolatile memory device which includes a nonvolatile memory element described in Embodiment 1. The following describes a configuration and operation of the nonvolatile memory device.

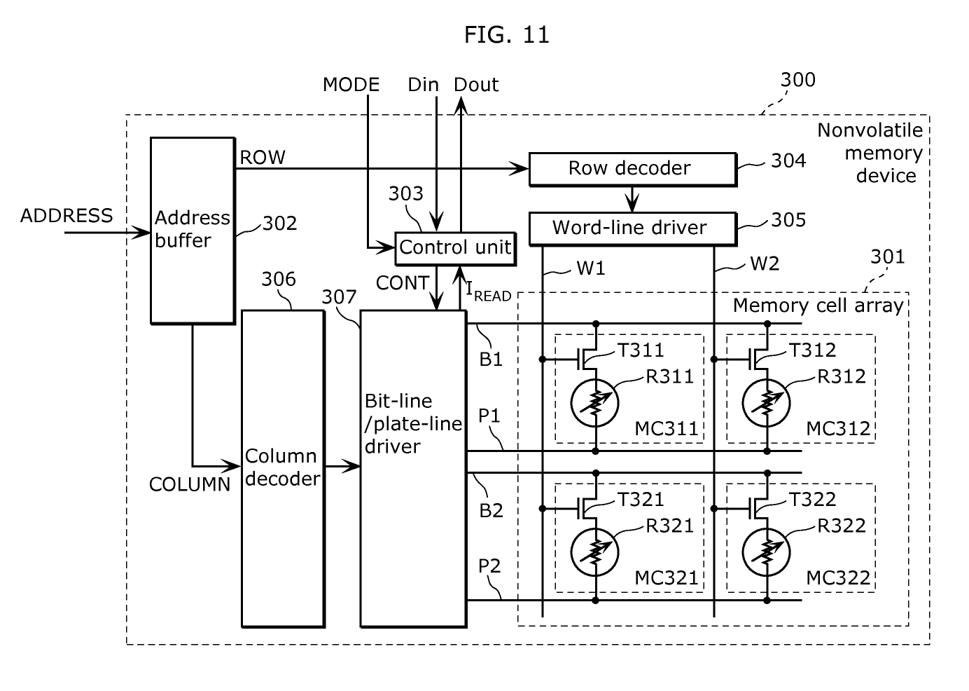

FIG. 11 is a block diagram showing an example of a configuration of a nonvolatile memory device according to Embodiment 2. As shown in FIG. 11, a nonvolatile memory device 300 according to this embodiment includes a memory cell array 301 including nonvolatile memory elements R311 to R322, an address buffer 302, a control unit 303, a row decoder 304, a word-line driver 305, a column decoder 306, and a bit-line/plate-line driver 307. The bit-line/plate-line driver 307 includes sense circuitry (sense amplifier) and can measure current flowing through bit lines or plate lines.

The memory cell array 301 includes two word lines W1 and W2 extending in parallel with each other, two bit lines B1 and B2 extending in parallel with each other crossing the word lines W1 and W2, two plate lines P1 and P2 provided with the bit lines B1 and B2 in one-to-one correspondence, respectively, and four memory cells MC311, MC312, MC321, and MC322 provided in matrix corresponding to cross points of the word lines W1 and W2 and the bit lines B1 and B2. The memory cells MC311, MC312, MC321, and MC322 include a selection transistor T311 and the nonvolatile memory element R311, a selection transistor T312 and the nonvolatile memory element R312, a selection transistor T321 and the nonvolatile memory element R321, and a selection transistor T322 and the nonvolatile memory element R322, respectively. Here, the nonvolatile memory elements R311 to R322 each correspond to the nonvolatile memory element 100 according to Embodiment 1.

Note that, the number of each of the structural elements is not limited to the above. For example, the memory cells included in the memory cell array 301 is not limited to four memory cells as described above, and may be five or more memory cells.

Note that, while in the above configuration example, the plate lines are disposed in parallel with the bit lines, the plate lines may be disposed in parallel with the word lines. Moreover, a configuration is used in which the plate line applies a common potential to the transistor connected thereto, but a configuration in which a source line selection circuit and a driver having the same configuration as the row decoder 304 and the word-line driver 305, respectively, and in which a selected source line and an unselected souse line are driven using different voltages (and different polarities) is also acceptable.

Further describing the configuration of the memory cell array 301, the memory cell MC311 (the selection transistor T311 and the nonvolatile memory element R311) is provided between the bit line B1 and the plate line P1 in a manner that a source of the selection transistor T311 and the nonvolatile memory element R311 are connected in series. More specifically, the selection transistor T311 is connected to the bit line B1 and the nonvolatile memory element R311 between the bit line B1 and the nonvolatile memory element R311, and the nonvolatile memory element R311 is connected to the selection transistor T311 and the plate line P1 between the selection transistor T311 and the plate line P1. A gate of the selection transistor T311 is connected to the word line W1. Note that, the other memory cells MC312, MC321, and MC322 have the same configuration as the memory cell MC311, and thus the description will be omitted.

According to the above configuration, when a predetermined voltage (an activation voltage) is supplied to each of the gates of the selection transistors T311, T312, T321, and T322 via the word lines W1 and W2, conduction between the drain and the source of each of the selection transistors T311, T312, T321, and T322 is permitted.

The address buffer 302 receives an address signal ADDRESS from an external circuit (not shown), and based on the address signal ADDRESS, outputs a row address signal ROW to the row decoder 304 and outputs a column address signal COLUMN to the column decoder 306. Here, the address signal ADDRESS is a signal indicating an address of a memory cell selected from among the memory cells MC311 to MC322. The row address signal ROW is a signal indicating a row address and the column address signal COLUMN is an address indicating a column address, in the address indicated by the address signal ADDRESS.

The control unit 303 selects one of an LR writing mode, an HR writing mode, a fluctuation-reducing mode, and a data reading mode according to a mode selection signal MODE received from the external circuit, and performs control corresponding to the selected mode. Note that, in this Description, the LR writing mode changes the nonvolatile memory element to the low resistance state, and the HR writing mode changes the nonvolatile memory element to the high resistance state. Furthermore, the fluctuation-reducing mode applies a voltage pulse which reduces a fluctuation of the nonvolatile memory element, and the reading mode reads data from the nonvolatile memory element (determines the resistance state of the nonvolatile memory element). Furthermore, the LR writing mode and the HR writing mode may collectively be simply referred to as a writing mode. Hereinafter, for voltage application, it is assumed that each voltage is applied based on the plate line.

In the LR writing mode, according to input data Din received from the external circuit, the control unit 303 outputs to the bit-line/plate-line driver 307 a control signal CONT instructing an “application of LR writing voltage pulse”.

In the case of the HR writing mode, the control unit 303 outputs to the bit-line/plate-line driver 307 a control signal CONT instructing an “application of HR writing voltage pulse”.

Furthermore, in the case of a reading mode, the control unit 303 outputs, to the bit-line/plate-line driver 307, a control signal CONT instructing an “application of fluctuation-reducing voltage” and an “application of reading voltage.” In the reading mode, the control unit 303 further receives a signal I_{READ} outputted from the bit-line/plate-line driver 307, and outputs, to the external circuit, output data Dout indicating a bit value according to the signal I_{READ}. The signal I_{READ} indicates a value of the current flowing through the plate lines P1 and P2 in the reading mode.

The row decoder 304 receives the row address signal ROW outputted from the address buffer 302, and selects one of the two word lines W1 and W2, according to the row address signal ROW. The word-line driver 305 applies the activation voltage to the word line selected by the row decoder 304, based on an output signal from the row decoder 304.

The column decoder 306 receives the column address signal COLUMN outputted from the address buffer 302, and according to the column address signal COLUMN, selects one of the two bit lines B1 and B2, and one of the two plate lines P1 and P2 that corresponds to the selected bit line.

Once receiving the control signal CONT instructing the “application of LR writing voltage pulse” from the control unit 303 in the LR writing mode, the bit-line/plate-line driver 307 applies an LR writing voltage V_{WRITE} (writing voltage pulse) between the bit line and the plate line, which are selected by the column decoder 306, based on an output signal from the column decoder 306. With this, a nonvolatile memory element of a memory cell designated by the address buffer 302 changes to a low resistance state.

Furthermore, once receiving the control signal CONT instructing the “application of HR writing voltage pulse” from the control unit 303 in the HR writing mode, the bit-line/plate-line driver 307 applies an HR writing voltage V_{RESET} (writing voltage pulse) between the bit line and the plate line, which are selected by the column decoder 306, based on the output signal from the column decoder 306. With this, a nonvolatile memory element of a memory cell designated by the address buffer 302 changes to a high resistance state.

Furthermore, in the fluctuation-reducing mode and the reading mode, once receiving the control signal CONT instructing the “application of fluctuation-reducing voltage” and the “application of reading voltage” from the control unit 303, the bit-line/plate-line driver 307 applies a fluctuation-reducing voltage V_{FLUC} (fluctuation-reducing voltage pulse) and a reading voltage V_{READ} (reading voltage pulse) between the bit line and the plate line, which are selected by the column decoder 306, based on the output signal from the column decoder 306.

Note that, in the case where the reading mode is executed a plurality of times in a period after the writing mode is executed and before the writing mode is executed next, various timing is conceivable for the execution of the fluctuation-reducing mode as described in Embodiment 1. For example, the fluctuation-reducing mode may be executed before each execution of the reading mode, the fluctuation-reducing mode may be executed only before the initial execution of the reading mode out of a plurality of times that the reading mode is executed, or the fluctuation-reducing mode may be executed every predetermined period of time. Furthermore, the fluctuation-reducing voltage V_{FLUC} may be collectively applied to a plurality of nonvolatile memory elements at the timing of the block read described above. After the application of the reading voltage V_{READ}, the bit line/plate line driver 307 outputs to the control unit 303 the signal I_{READ} indicating a value of a current flowing in the plate line. The control unit 303 determines, based on the signal I_{READ}, which resistance state, out of the high resistance state and the low resistance state, the nonvolatile memory element is in, and outputs the output data Dout indicating a bit value obtained as a result of the determination.

Here, values of the LR writing voltage V_{WRITE} and the HR writing voltage V_{RESET} are set to, for example, −2.4 V and +2.0 V, respectively, and the pulse width in both cases is set to 100 ns. A value of the reading voltage V_{READ} is set to, for example, +0.4 V. A value of the fluctuation-reducing voltage V_{FLUC} is set to, for example, +0.7 V or −0.7 V, and the pulse width is set to 100 ns.

In this manner, it is possible to reduce the error in reading data due to the effect of fluctuation, by applying the fluctuation-reducing voltage pulse to the nonvolatile memory element in the fluctuation-reducing mode.

Note that, although the above described an example in which all the HR writing voltage pulse (first voltage pulse), the LR writing voltage pulse (second voltage pulse), the fluctuation-reducing voltage pulse (third voltage pulse), and the reading voltage pulse (fourth voltage pulse) are applied by the bit line/plate line driver 307, this embodiment is not limited to such an example. For example, an HR writing voltage application unit which applies the HR writing voltage pulse, an LR writing voltage application unit which applies the LR writing voltage pulse, a fluctuation-reducing voltage application unit (first voltage application unit) which applies the fluctuation-reducing voltage pulse, and a reading voltage application unit (second voltage application unit) which applies the reading voltage pulse may be separate circuits or may partly share circuits.

Furthermore, although a voltage pulse is applied to reduce the fluctuation in the above-described embodiment, similar advantageous effects are produced with application of a current pulse.

As described above, it is believed that the fluctuation phenomenon is caused by electrons being captured or released by dangling bonds present in the minute filament. In this embodiment, the amount of fluctuation in resistance value is reduced by intentionally capturing and releasing the electrons. Although the above embodiment described an example in which a voltage pulse of negative polarity is applied between the electrodes to inject an electron into a filament to cause a dangling bond in a filament to capture an electron, an electron can be injected to a filament in a similar manner with a current pulse as well.

### Embodiment 3

Embodiment 3 is a cross-point nonvolatile memory device which includes the nonvolatile memory element described in Embodiment 1. Here, the cross-point nonvolatile memory device is a memory device in which an active layer is positioned at a cross-point (three-dimensional cross-point) of the word line and the bit line. The following describes a configuration and operation of the nonvolatile memory device.

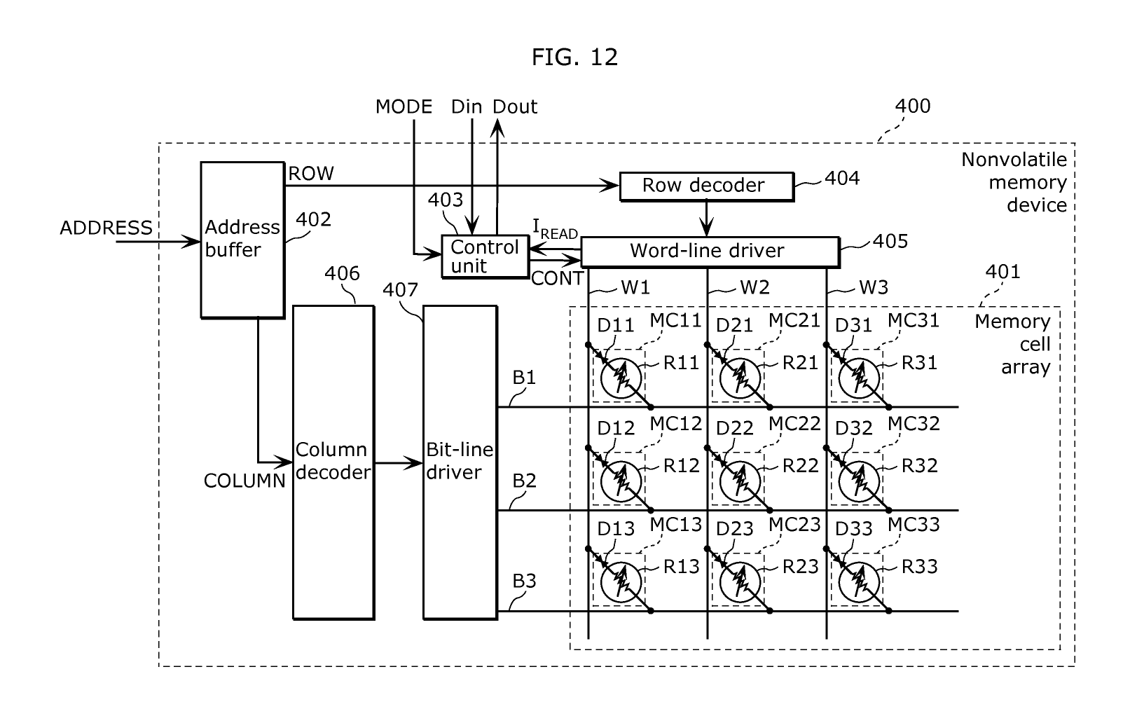

FIG. 12 is a block diagram showing an example of a configuration of a nonvolatile memory device according to Embodiment 3. As shown in FIG. 12, a nonvolatile memory device 400 according to this embodiment includes a memory cell array 401 including nonvolatile memory elements R11 to R33, an address buffer 402, a control unit 403, a row decoder 404, a word-line driver 405, a column decoder 406, and a bit-line driver 407. The bit-line driver 407 includes a sense circuitry and can measure the current flowing through the bit lines.

The memory cell array 401 includes a plurality of word lines W1, W2, and W3 formed extending in parallel with one another, and bit lines B1, B1, and B3 formed extending in parallel with one another crossing the word lines W1, W2, and W3. Here, the word lines W1, W2, and W3 are formed in a first plane parallel with the main surface of a substrate (not shown), and the bit lines B1, B1, and B3 are formed in a second plane located above or below the first plane and substantially in parallel with the first plane. Thus, the word lines W1, W2, and W3 and the bit lines B1, B1, and B3 are three-dimensionally crossing each other. Corresponding to the three-dimensional cross-points, a plurality of memory cells MC11, MC12, MC13, MC21, MC22, MC23, MC31, MC32, and MC33 (hereinafter, represented as “memory cells MC11, MC12, and so on”) are provided.

Memory cells MC11, MC12, and so on each include a corresponding one of the nonvolatile memory elements R11, R12, R13, R21, R22, R23, R31, R32, and R33 and a corresponding one of current steering elements D11, D12, D13, D21, D22, D23, D31, D32, and D33 which includes, for example, a bidirectional diode, connected in series. The nonvolatile memory elements R11 to R33 are each connected to a corresponding one of the bit lines B1, B1, and B3, and the current steering elements D11 to D33 are each connected to a corresponding one of the nonvolatile memory elements and a corresponding one of the word lines W1, W2, and W3. Here, the nonvolatile memory elements R11 to R22 each correspond to the nonvolatile memory element 100 according to Embodiment 1. Examples of the current steering elements D11 to D33 include MIM (Metal Insulator Metal) diodes, MSM (Metal Semiconductor Metal) diodes, and varistors.

Note that, as with Embodiment 2, the number of each of the structural elements is not limited to the above.

The address buffer 402 receives an address signal ADDRESS from an external circuit (not shown), and based on the address signal ADDRESS, outputs a row address signal ROW to the row decoder 404 and outputs a column address signal COLUMN to the column decoder 406. Here, the address signal ADDRESS is a signal indicating an address of a memory cell selected from among the memory cells MC11, MC12, and so on. The row address signal ROW is a signal indicating a row address in the address indicated by the address signal ADDRESS and the column address signal COLUMN is a signal indicating a column address in the address indicated by the address signal ADDRESS.

According to the mode selection signal MODE received from the external circuit, the control unit 403 selects one of an LR writing mode, an HR writing mode, and a reading mode, and performs control corresponding to the selected mode. Hereinafter, for voltage application, it is assumed that each voltage is applied based on the bit line.

In the LR writing mode and the HR writing mode, according to an input data Din received from the external circuit, the control unit 403 outputs an LR writing voltage pulse and an HR writing voltage pulse to the word-line driver 405. With this, a nonvolatile memory element of a memory cell designated by the address buffer 402 changes to a low resistance state or a high resistance state.

In a reading mode, the control unit 403 outputs the fluctuation-reducing voltage pulse and the reading voltage pulse to the word-line driver 405. Note that, various timing is conceivable for application of a fluctuation-reducing voltage V_{FLUC} as with Embodiment 2. In the reading mode, the control unit 403 further detects the value of the current flowing between the bit line B2 and the word line W2, and outputs the output data Dout indicating a bit value corresponding to the current value to the external circuit.

The row decoder 404 receives the row address signal ROW outputted from the address buffer 402, and selects one of the word lines W1, W2, and W3, according to the row address signal ROW. The word-line driver 405 applies a predetermined voltage to the word line selected by the row decoder 404, based on an output signal from the row decoder 404.

The column decoder 406 receives the column address signal COLUMN outputted from the address buffer 402, and selects one of the bit lines B1, B2, and B3, according to the column address signal COLUMN.

The bit-line driver 407 grounds the bit line selected by the column decoder 406, based on an output signal from the column decoder 406.

Although the methods for reading data from the nonvolatile memory elements and the nonvolatile memory devices according to the present invention have been described thus far based on Embodiments 1 to 3, the present invention is not limited to these embodiments. Embodiments resulting from various modifications of the embodiments as well as embodiments resulting from arbitrary combinations of structural elements of the different embodiments that may be conceived by those skilled in the art are intended to be included within the scope of the present invention as long as these do not depart from the essence of the present invention.

For example, the nonvolatile memory devices according to the present invention need not necessarily include word line drivers and bit line drivers. Furthermore, other than the cross-point nonvolatile memory device, the nonvolatile memory devices according to the present invention may be for example, a 1T1R nonvolatile memory device including a memory cell which includes a transistor and a nonvolatile memory element. Furthermore, the nonvolatile memory device may include an offset current sensing cell having a resistance value higher than a resistance value of a memory element in a high resistance state in which a memory element performs a memory operation.

Furthermore, although this embodiment is a one-layered cross-point nonvolatile memory device, this embodiment may be a multi-layered cross-point nonvolatile memory device by stacking memory cell arrays.

Furthermore, the positional relationship between the nonvolatile memory element and the current steering element may be transposed. In other words, the word lines may be connected to the nonvolatile memory elements, and the bit lines may be connected to the current steering elements.

Moreover, the bit lines and/or the word lines may also function as electrodes in the nonvolatile memory element.

In the nonvolatile memory device according to Embodiment 3 described above as well, it becomes possible to reduce the error in reading data due to the effect of fluctuation, with an application of the fluctuation-reducing voltage pulse according to need in the fluctuation-reducing mode.

Furthermore, although the nonvolatile memory device in each of the above-described embodiments does not explicitly describes a circuit which performs writing to a memory cell and a circuit which performs an initial breakdown operation, the nonvolatile memory device may include such circuits.

### INDUSTRIAL APPLICABILITY

A method for reading data from a nonvolatile memory element and a nonvolatile memory device according to the present invention are useful respectively as a method of reading data from a nonvolatile memory element and as a memory device for use in a variety of electronic devices, such as personal computers and mobile phones.

### REFERENCE SIGNS LIST

100, 201, R11 to R33, R311 to R322 Nonvolatile memory element
101 Substrate
102 Interlayer dielectric
103 First electrode
104 Variable resistance layer
104a First oxide layer
104b Second oxide layer
105 Second electrode
106 Local region
202 Load resistance
203, 204 Terminal
300, 400 Nonvolatile memory device
301, 401 Memory cell array
302, 402 Address buffer
303, 403 Control unit
304, 404 Row decoder
305, 405 Word line driver
306, 406 Column decoder
307 Bit line/plate line driver
407 Bit line driver
MC11 to MC33, MC311 to MC322 Memory cell
T311 to T322 Selection transistor
D11 to D33 Current steering element

1. A method for reading data from a variable resistance nonvolatile memory element which
(i) includes a first electrode, a second electrode, and a variable resistance layer which is positioned between the first electrode and the second electrode, comprises a metal oxide, and includes a local region having a degree of oxygen deficiency higher than a degree of oxygen deficiency of a surrounding region of the local region,
(ii) has a characteristic that the variable resistance layer changes from a low resistance state to a high resistance state in response to application of a first voltage pulse between the first electrode and the second electrode, and the variable resistance layer changes from the high resistance state to the low resistance state in response to application of a second voltage pulse between the first electrode and the second electrode, and
(iii) stores data corresponding to the resistance state of the variable resistance layer,
the method comprising:
applying a third voltage pulse between the first electrode and the second electrode of the variable resistance layer which has been changed to the high resistance state or the low resistance state, the third voltage pulse having a voltage with an absolute value smaller than absolute values of voltages of the first voltage pulse and the second voltage pulse; and
reading the resistance state of the variable resistance layer by applying a fourth voltage pulse between the first electrode and the second electrode after the applying of a third voltage pulse, the fourth voltage pulse having a voltage with an absolute value smaller than the absolute values of the voltages of the first voltage pulse and the second voltage pulse.

2. The method according to claim 1,
wherein the local region is formed toward the first electrode from the second electrode, the local region being in contact with the second electrode and not in contact with the first electrode.

3. The method according to claim 1,
wherein the variable resistance layer has a fluctuation characteristic that a resistance value randomly changes over time.

4. The method according claim 1,
wherein the variable resistance layer includes a first oxide layer and a second oxide layer which has a degree of oxygen deficiency higher than a degree of oxygen deficiency of the first oxide layer, and
the local region has a degree of oxygen deficiency higher than the degree of oxygen deficiency of the first oxide layer.

5. The method according to claim 4,
wherein the first oxide layer is in contact with the second electrode, and
the local region is in contact with the second electrode and formed toward the first electrode from the second electrode, the local region penetrating the first oxide layer.

6. The method according to claim 1,
wherein when the reading of the resistance state is repeated a plurality of times in a period after data is stored and before the resistance state of the nonvolatile memory element is changed next, the nonvolatile memory element executes the applying of a third voltage pulse before each of the plurality of times that the reading of the resistance state is executed.

7. The method according to claim 1,
wherein the first voltage pulse and the second voltage pulse are different in polarity.

8. The method according to claim 1,
wherein in the applying of a third voltage pulse, the third voltage pulse having the voltage with the absolute value greater than the absolute value of the voltage of the fourth voltage pulse is applied between the first electrode and the second electrode.

9. The method according to claim 1,
wherein the first voltage pulse and the third voltage pulse are identical in polarity.

10. The method according to claim 1,
wherein the second voltage pulse and the third voltage pulse are identical in polarity.

11. A method for reading data from a variable resistance nonvolatile memory element which
(i) includes a first electrode, a second electrode, and a variable resistance layer which is positioned between the first electrode and the second electrode, comprises a metal oxide, and includes a local region having a degree of oxygen deficiency higher than a degree of oxygen deficiency of a surrounding region of the local region,
(ii) has a characteristic that the variable resistance layer changes from a low resistance state to a high resistance state in response to application of a first current pulse between the first electrode and the second electrode, and the variable resistance layer changes from the high resistance state to the low resistance state in response to application of a second current pulse between the first electrode and the second electrode, and
(iii) stores data corresponding to the resistance state of the variable resistance layer,
the method comprising:
applying a third current pulse between the first electrode and the second electrode of the variable resistance layer which has been changed to the high resistance state or the low resistance state, the third current pulse having a current with an absolute value smaller than absolute values of currents of the first current pulse and the second current pulse; and
reading the resistance state of the variable resistance layer by applying a fourth current pulse between the first electrode and the second electrode after the applying of a third current pulse, the fourth current pulse having a current with an absolute value smaller than the absolute values of the currents of the first current pulse and the second current pulse.

12. The method according to claim 11,
wherein the local region is formed toward the first electrode from the second electrode, the local region being in contact with the second electrode and not in contact with the first electrode.

13. The method according to claim 11,
wherein the variable resistance layer has a fluctuation characteristic that a resistance value randomly changes over time.

14. The method according to claim 11,
wherein the variable resistance layer includes a first oxide layer and a second oxide layer which has a degree of oxygen deficiency higher than a degree of oxygen deficiency of the first oxide layer, and
the local region has a degree of oxygen deficiency higher than the degree of oxygen deficiency of the first oxide layer.

15. The method according to claim 14,
wherein the first oxide layer is in contact with the second electrode, and
the local region is in contact with the second electrode and formed toward the first electrode from the second electrode, the local region penetrating the first oxide layer.

16. The method according to claim 11,
wherein when the reading of the resistance state is repeated a plurality of times in a period after data is stored and before the resistance state of the nonvolatile memory element is changed next, the nonvolatile memory element executes the applying of a third current pulse before each of the plurality of times that the reading of the resistance state is executed.

17. The method according to claim 11,
wherein the first current pulse and the second current pulse are different in polarity.

18. The method according to claim 11,
wherein in the applying of a third current pulse, the third current pulse having the current with the absolute value greater than the absolute value of the current of the fourth current pulse is applied between the first electrode and the second electrode.

19. The method according to claim 11,
wherein the first current pulse and the third current pulse are identical in polarity.

20. The method according to claim 11,
wherein the second current pulse and the third current pulse are identical in polarity.

21. The method according to claim 1,
wherein the metal oxide is a tantalum oxide.

22. A nonvolatile memory device including a variable resistance nonvolatile memory element which
(i) includes a first electrode, a second electrode, and a variable resistance layer which is positioned between the first electrode and the second electrode, comprises a metal oxide, and includes a local region having a degree of oxygen deficiency higher than a degree of oxygen deficiency of a surrounding region of the local region,
(ii) has a characteristic that the variable resistance layer changes from a low resistance state to a high resistance state in response to application of a first voltage pulse between the first electrode and the second electrode, and the variable resistance layer changes from the high resistance state to the low resistance state in response to application of a second voltage pulse between the first electrode and the second electrode, and
(iii) stores data corresponding to the resistance state of the variable resistance layer,
the nonvolatile memory device comprising:
a first voltage application unit configured to apply a third voltage pulse between the first electrode and the second electrode of the variable resistance layer which has been changed to the high resistance state or the low resistance state, the third voltage pulse having a voltage with an absolute value smaller than absolute values of voltages of the first voltage pulse and the second voltage pulse;
a second voltage application unit configured to apply a fourth voltage pulse between the first electrode and the second electrode of the variable resistance layer which has been changed to the high resistance state or the low resistance state, the fourth voltage pulse being for reading and having a voltage with an absolute value smaller than the absolute values of the voltages of the first voltage pulse and the second voltage pulse; and
a control unit configured to selectively execute (i) a fluctuation-reducing mode in which a control signal is outputted for instructing the first voltage application unit to apply the third voltage pulse and (ii) a data reading mode in which a control signal is outputted for instructing the second voltage application unit to apply the fourth voltage pulse after the fluctuation-reducing mode.

23. The nonvolatile memory device according to claim 22,
wherein the local region is formed toward the first electrode from the second electrode, the local region being in contact with the second electrode and not in contact with the first electrode.

24. The nonvolatile memory device according to claim 22,
wherein the variable resistance layer has a fluctuation characteristic that a resistance value randomly changes over time.

25. The nonvolatile memory device according to claim 22,
wherein when the data reading mode is executed a plurality of times, the control unit is configured to execute the fluctuation-reducing mode before each of the plurality of times that the data reading mode is executed.

26. The nonvolatile memory device according to claim 22,
wherein the first voltage pulse and the second voltage pulse are different in polarity.

27. The nonvolatile memory device according to claim 22,
wherein the variable resistance layer includes a first oxide layer and a second oxide layer which has a degree of oxygen deficiency higher than a degree of oxygen deficiency of the first oxide layer, and
the first oxide layer includes the local region which has a degree of oxygen deficiency higher than the degree of oxygen deficiency of the first oxide layer.

28. The nonvolatile memory device according to claim 27,
wherein the first oxide layer is in contact with the second electrode, and
the local region is in contact with the second electrode and formed toward the first electrode from the second electrode, the local region penetrating the first oxide layer.

29. The nonvolatile memory device according to claim 22,
wherein the first voltage application unit is configured to apply the third voltage pulse between the first electrode and the second electrode, the third voltage pulse having the voltage with the absolute value greater than the absolute value of the voltage of the fourth voltage pulse.

30. The nonvolatile memory device according to claim 22,
wherein the first voltage pulse and the third voltage pulse are identical in polarity.

31. The nonvolatile memory device according to claim 22,
wherein the second voltage pulse and the third voltage pulse are identical in polarity.

32. A nonvolatile memory device including a variable resistance nonvolatile memory element which
(i) includes a first electrode, a second electrode, and a variable resistance layer which is positioned between the first electrode and the second electrode, comprises a metal oxide, and includes a local region having a degree of oxygen deficiency higher than a degree of oxygen deficiency of a surrounding region of the local region,
(ii) has a characteristic that the variable resistance layer changes from a low resistance state to a high resistance state in response to application of a first current pulse between the first electrode and the second electrode, and the variable resistance layer changes from the high resistance state to the low resistance state in response to application of a second current pulse between the first electrode and the second electrode, and
(iii) stores data corresponding to the resistance state of the variable resistance layer,
the nonvolatile memory device comprising:
a first current application unit configured to apply a third current pulse between the first electrode and the second electrode of the variable resistance layer which has been changed to the high resistance state or the low resistance state, the third current pulse having a current with an absolute value smaller than absolute values of currents of the first current pulse and the second current pulse;
a second current application unit configured to apply a fourth current pulse between the first electrode and the second electrode of the variable resistance layer which has been changed to the high resistance state or the low resistance state, the fourth current pulse being for reading and having a current with an absolute value smaller than the absolute values of the currents of the first current pulse and the second current pulse; and
a control unit configured to selectively execute (i) a fluctuation-reducing mode in which a control signal is outputted for instructing the first current application unit to apply the third current pulse and (ii) a data reading mode in which a control signal is outputted for instructing the second current application unit to apply the fourth current pulse after the fluctuation-reducing mode.

33. The nonvolatile memory device according to claim 32,
wherein the local region is formed toward the first electrode from the second electrode, the local region being in contact with the second electrode and not in contact with the first electrode.

34. The nonvolatile memory device according to claim 32,
wherein the variable resistance layer has a fluctuation characteristic that a resistance value randomly changes over time.

35. The nonvolatile memory device according to claim 32,
wherein when the data reading mode is executed a plurality of times, the control unit is configured to execute the fluctuation-reducing mode before each of the plurality of times that the data reading mode is executed.

36. The nonvolatile memory device according to claim 32,
wherein the first current pulse and the second current pulse are different in polarity.

37. The nonvolatile memory device according to claim 32,
wherein the variable resistance layer includes a first oxide layer and a second oxide layer which has a degree of oxygen deficiency higher than a degree of oxygen deficiency of the first oxide layer, and
the first oxide layer includes the local region which has a degree of oxygen deficiency higher than the degree of oxygen deficiency of the first oxide layer.

38. The nonvolatile memory device according to claim 37
wherein the first oxide layer is in contact with the second electrode, and
the local region is in contact with the second electrode and formed toward the first electrode from the second electrode, the local region penetrating the first oxide layer.

39. The nonvolatile memory device according to claim 32,
wherein the first current application unit is configured to apply the third current pulse between the first electrode and the second electrode, the third current pulse having the current with the absolute value greater than the absolute value of the current of the fourth current pulse.

40. The nonvolatile memory device according to claim 32,
wherein the first current pulse and the third current pulse are identical in polarity.

41. The nonvolatile memory device according to claim 32,
wherein the second current pulse and the third current pulse are identical in polarity.

42. The nonvolatile memory device according to claim 32,
wherein the metal oxide is a tantalum oxide.
